(19) United States
(12) Patent Application Publication
(10) Pub. No.: US 2016/0018454 A1
(43) Pub. Date: Jan. 21, 2016

(54) LEAKAGE CURRENT DETECTION DEVICE, INTEGRATED CIRCUIT DEVICE HAVING THE SAME, AND METHOD OF DETECTING LEAKAGE CURRENT IN NONVOLATILE MEMORY DEVICE

(71) Applicants: BYUNG-GIL JEON, SUWON-SI (KR); OH-SUK KWON, SEOUL (KR); DOO-GON KIM, HWASEONG-SI (KR); SUNG-WHAN SEO, HWASEONG-SI (KR)

(72) Inventors: BYUNG-GIL JEON, SUWON-SI (KR); OH-SUK KWON, SEOUL (KR); DOO-GON KIM, HWASEONG-SI (KR); SUNG-WHAN SEO, HWASEONG-SI (KR)

(21) Appl. No.: 14/736,503

(22) Filed: Jun. 11, 2015

(30) Foreign Application Priority Data
Jul. 15, 2014 (KR) 10-2014-0089360

(51) Int. Cl. G01R 31/02

(52) U.S. Cl. CPC G01R 31/025

(57) ABSTRACT

A leakage current detection device includes a drive voltage generation circuit, a reference voltage generation circuit, a first capacitor, a second capacitor, a comparator, and a latch circuit. The drive voltage generation circuit provides a drive voltage to a test line in response to a charge control signal to charge the test line. The reference voltage generation circuit generates a first reference voltage and a second reference voltage, and provides the first reference voltage to a detection node in response to a switch control signal. The first capacitor is coupled between the test line and the detection node. The second capacitor is coupled between the detection node and a ground voltage. The comparator outputs a comparison signal by comparing a voltage of the detection node with the second reference voltage. The latch circuit latches the comparison signal, and outputs the latched comparison signal as a test result signal.

### CROSS-REFERENCE TO RELATED APPLICATION(S)

This application claims priority under 35 USC §119 to Korean Patent Application No. 10-2014-0089360, filed on Jul. 15, 2014 in the Korean Intellectual Property Office (KIPO), the contents of which are herein incorporated by reference in their entirety.

### BACKGROUND

1. Technical Field

The application relates to a leakage current detection device, a nonvolatile memory device including the leakage current detection device, and a method of detecting a leakage current in a nonvolatile memory device.

2. Description of the Related Art

Memory devices can be broadly classified into two groups based on whether they retain stored data when disconnected from power. These groups include volatile memory devices, which lose stored data when disconnected from power, and nonvolatile memory devices, which retain stored data when disconnected from power.

Examples of volatile memory devices include dynamic random access memory (DRAM), and static random access memory (SRAM), and examples of nonvolatile memory devices include electrically erasable and programmable read only memory (EEPROM), phase-change random access memory (PRAM), resistance random access memory (RRAM), and magnetic random access memory (MRAM).

EEPROM is one of the more common forms of nonvolatile memory in use today due to its ability to be efficiently programmed, read, and erased. Flash EEPROM (hereafter, “flash memory”), for instance, can be found in a wide range of modern electronic devices, including solid state drives, mobile phones, digital cameras, and many others.

Memory cells included in flash memory devices are coupled to drive lines. Flash memory devices perform program, read, and erase operations on the memory cells by applying drive signals to the drive lines.

If a drive line has a defect such that a leakage current flows from the drive line, program, read, and erase operations may not be performed correctly on memory cells coupled to the drive line having a defect. Therefore, data stored in the memory cells coupled to the drive line having a defect may be lost.

### SUMMARY

Some example embodiments are directed to provide a leakage current detection device that effectively detects a leakage current flowing from a drive line coupled to a memory cell array of a nonvolatile memory device.

Some example embodiments are directed to provide a nonvolatile memory device including the leakage current detection device.

Some example embodiments are directed to provide a method of detecting a leakage current that effectively detects a leakage current flowing from a drive line coupled to a memory cell array of a nonvolatile memory device.

According to example embodiments, a leakage current detection device includes a drive voltage generation circuit, a reference voltage generation circuit, a first capacitor, a second capacitor, a comparator, and a latch circuit. The drive voltage generation circuit provides a drive voltage to a test line in response to a charge control signal to charge the test line. The reference voltage generation circuit generates a first reference voltage and a second reference voltage, and provides the first reference voltage to a detection node in response to a switch control signal. The first capacitor is coupled between the test line and the detection node. The second capacitor is coupled between the detection node and a ground voltage. The comparator outputs a comparison signal by comparing a voltage of the detection node with the second reference voltage. The latch circuit latches the comparison signal in response to a latch control signal, and outputs the latched comparison signal as a test result signal indicating whether a leakage current flows from the test line.

In example embodiments, the drive voltage generation circuit may include a drive voltage generator configured to generate the drive voltage, and a switch coupled between the drive voltage generator and the test line, and being turned on in response to the charge control signal.

The drive voltage generator may adjust a magnitude of the drive voltage based on a voltage control signal.

In example embodiments, the reference voltage generation circuit may include a reference voltage generator, and a first switch. The reference voltage generator may generate the first reference voltage and output the first reference voltage through a first output electrode. The reference voltage generator may generate the second reference voltage by dropping a voltage level of the first reference voltage and provide the second reference voltage to the comparator through a second output electrode. The first switch may be coupled between the first output electrode of the reference voltage generator and the detection node, and be turned on in response to the switch control signal.

The leakage current detection device may further include a control circuit configured to generate the charge control signal, the switch control signal, and the latch control signal. The control circuit may activate the charge control signal and the switch control signal at a first time, deactivate the charge control signal and the switch control signal at a second time, and provide the latch control signal to the latch circuit at a third time. The time duration between the second time and the third time may correspond to a detection time.

The control circuit may adjust a length of the detection time based on a magnitude of the leakage current of the test line to be detected.

The leakage current detection device may further include a second switch coupled between the detection node and the ground voltage. The second switch may be turned on in response to a ground control signal after the latch circuit outputs the test result signal in response to the latch control signal.

In example embodiments, the reference voltage generation circuit may include a switch and a reference voltage generator. The switch may be coupled between the detection node and the ground voltage. The switch may be turned on to provide the ground voltage to the detection node as the first reference voltage when the switch control signal is activated. The switch may be turned off to float the detection node when the switch control signal is deactivated. The reference voltage generator may generate the second reference voltage and to provide the second reference voltage to the comparator.

The leakage current detection device may further include a control circuit configured to generate the charge control signal, the switch control signal, and the latch control signal. The control circuit may activate the charge control signal and deactivate the switch control signal at a first time, deactivate the charge control signal at a second time, and provide the latch control signal to the latch circuit at a third time. The time duration between the second time and the third time may correspond to a detection time.

In example embodiments, the test line may correspond to a word line coupled to a memory cell array of a nonvolatile memory device.

In example embodiments, the test line may correspond to a string selection line coupled to a memory cell array of a nonvolatile memory device.

In example embodiments, the test line may correspond to a ground selection line coupled to a memory cell array of a nonvolatile memory device.

According to example embodiments, a nonvolatile memory device includes a memory cell array, a line selection circuit, a drive voltage generation circuit, a reference voltage generation circuit, a first capacitor, a second capacitor, a comparator, and a latch circuit. The memory cell array includes a plurality of memory cell strings. The line selection circuit is coupled to the plurality of memory cell strings through a string selection line, a plurality of word lines, and a ground selection line. The line selection circuit connects a test line to one of the string selection line, the plurality of word lines, and the ground selection line based on a test line selection signal. The drive voltage generation circuit provides a drive voltage to the test line in response to a charge control signal to charge the test line. The reference voltage generation circuit generates a first reference voltage and a second reference voltage, and provides the first reference voltage to a detection node in response to a switch control signal. The first capacitor is coupled between the test line and the detection node. The second capacitor is coupled between the detection node and a ground voltage. The comparator outputs a comparison signal by comparing a voltage of the detection node with the second reference voltage. The latch circuit latches the comparison signal in response to a latch control signal, and outputs the latched comparison signal as a test result signal.

In example embodiments, the reference voltage generation circuit may include a reference voltage generator, and a first switch. The reference voltage generator may generate the first reference voltage and output the first reference voltage through a first output electrode. The reference voltage generator may generate the second reference voltage by dropping a voltage level of the first reference voltage and provide the second reference voltage to the comparator through a second output electrode. The first switch may be coupled between the first output electrode of the reference voltage generator and the detection node, and be turned on in response to the switch control signal.

The nonvolatile memory device may further include a second switch coupled between the detection node and the ground voltage. The second switch may be turned on in response to a ground control signal.

The nonvolatile memory device may further include a current source and a third switch. The current source may be coupled to the ground voltage, and generate a constant current having a predetermined magnitude. The third switch may be coupled between the test line and the current source, and be turned on in response to a preset control signal.

The nonvolatile memory device may further include a controller configured to generate the charge control signal, the switch control signal, the ground control signal, the preset control signal, and the latch control signal. The controller may activate the charge control signal, the switch control signal, and the preset control signal and deactivate the ground control signal at a first time, deactivate the charge control signal and the switch control signal at a second time, and determine a detection time as a time duration between the second time and a time at which a logic level of the comparison signal changes. The controller may activate the charge control signal and the switch control signal and deactivate the ground control signal and the preset control signal at a third time, deactivate the charge control signal and the switch control signal at a fourth time, provide the latch control signal to the latch circuit at a fifth time, and activate the ground control signal at a sixth time. The time duration between the fourth time and the fifth time may correspond to the detection time.

In example embodiments, the reference voltage generation circuit may include a switch, and a reference voltage generator. The switch may be coupled between the detection node and the ground voltage. The switch may be turned on to provide the ground voltage to the detection node as the first reference voltage when the switch control signal is activated. The switch may be turned off to float the detection node when the switch control signal is deactivated. The reference voltage generator may generate the second reference voltage and provide the second reference voltage to the comparator.

In a method of detecting a leakage current in a nonvolatile memory device, a first reference voltage and a second reference voltage lower than the first reference voltage are generated. A test line, which is coupled to a string selection line, one of a plurality of word lines, or a ground selection line that is coupled to a memory cell array, is charged by providing a drive voltage to the test line. The first reference voltage is applied to a detection node, which is coupled to the test line through a first capacitor and is coupled to a ground voltage through a second capacitor. The test line and the detection node are floated. A test result signal, which indicates whether a leakage current flows from the test line, is generated by comparing a voltage of the detection node with the second reference voltage, after a detection time from a time at which the test line and the detection node are floated.

In example embodiments, the detection node may be connected to the ground voltage after generating the test result signal.

In example embodiments, a method of testing a nonvolatile memory device includes applying a charge voltage to a signal line of a memory cell array of the memory device and detecting an indication of the amount of leakage current flowing through the signal line of the memory cell array.

In example embodiments, the method further includes discontinuing the application of the charge voltage to the signal line. The indication of the amount of leakage current flowing through the signal line is detected by comparing an indicator of the voltage existing on the signal line to a reference value, after a predetermined period of time has expired from discontinuing the application of the charge voltage to the signal line.

In example embodiments, the method further includes applying the charge voltage to a reference signal line of a standard nonvolatile memory cell array, discontinuing the application of the charge voltage to the reference signal line, and determining, based upon an indicator of the voltage existing on the reference signal line, the amount of time expiring before the voltage existing on the reference test line decays to a standard value after discontinuing the application of the charge voltage to the reference signal line. The value of the predetermined period of time is set based upon the determined amount of time expiring before the voltage existing on the reference signal line decays to the standard value.

In example embodiments, an apparatus for testing a nonvolatile memory device includes a voltage generator that applies a charge voltage to a signal line of a nonvolatile memory cell array and, upon charging the signal line, discontinues the application of the charge voltage. A comparator compares an indicator of the voltage existing on the signal line to a reference value, after a predetermined period of time has expired from discontinuing the application of the charge voltage, to generate an indicator of the quality of the memory cell array.

In example embodiments, the apparatus further includes a first capacitor having a first electrode electrically connected to the signal line and a second electrode electrically connected to an electrical node. A second capacitor has a first electrode electrically connected to the electrical node and a second electrode electrically connected to ground potential. The indicator of the voltage existing on the signal line is the voltage existing at the electrical node.

In example embodiments, an integrated circuit chip includes an array of nonvolatile memory cells that each store data, a data input/output circuit that provides data to the memory cells for storage and retrieves data stored in the memory cells, and a leakage-current detector that detects an indication of the amount of leakage current flowing through a signal line of the memory cells.

### BRIEF DESCRIPTION OF THE DRAWINGS

Illustrative, non-limiting example embodiments will be more clearly understood from the following detailed description in conjunction with the accompanying drawings.

FIG. 1 is a block diagram illustrating a leakage current detection device according to example embodiments.

FIG. 2 is a block diagram illustrating an example of a leakage current detection device of FIG. 1.

FIGS. 3 and 4 are timing diagrams for describing an operation of the leakage current detection device of FIG. 2.

FIG. 5 is a block diagram illustrating an example of a leakage current detection device of FIG. 1.

FIGS. 6 and 7 are timing diagrams for describing an operation of the leakage current detection device of FIG. 5.

FIG. 8 is a block diagram illustrating an example of a leakage current detection device of FIG. 1.

FIGS. 9 and 10 are timing diagrams for describing an operation of the leakage current detection device of FIG. 8.

FIG. 11 is a block diagram illustrating a nonvolatile memory device according to example embodiments.

FIGS. 12A and 12B are circuit diagrams illustrating examples of a memory cell array included in the nonvolatile memory device of FIG. 11.

FIG. 13 is a block diagram illustrating an example of a nonvolatile memory device of FIG. 11.

FIG. 14 is a block diagram illustrating an example of a nonvolatile memory device of FIG. 11.

FIGS. 15, 16 and 17 are timing diagrams for describing an operation of the nonvolatile memory device of FIG. 14.

FIG. 18 is a block diagram illustrating a nonvolatile memory device according to example embodiments.

FIG. 19 is a flow chart illustrating a method of detecting a leakage current in a nonvolatile memory device according to example embodiments.

FIG. 20 is a block diagram illustrating a memory system according to example embodiments.

FIG. 21 is a block diagram illustrating a memory card according to example embodiments.

FIG. 22 is a block diagram illustrating a solid state drive (SSD) system according to example embodiments.

FIG. 23 is a block diagram illustrating a mobile system according to example embodiments.

### DETAILED DESCRIPTION OF THE EMBODIMENTS

Various example embodiments will be described more fully with reference to the accompanying drawings, in which some example embodiments are shown. The present application may, however, be embodied in many different forms and should not be construed as limited to the embodiments set forth herein. Rather, these embodiments are provided so that this disclosure will be thorough and complete, and will fully convey the scope of the present application to those skilled in the art Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present application. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the application. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this application belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

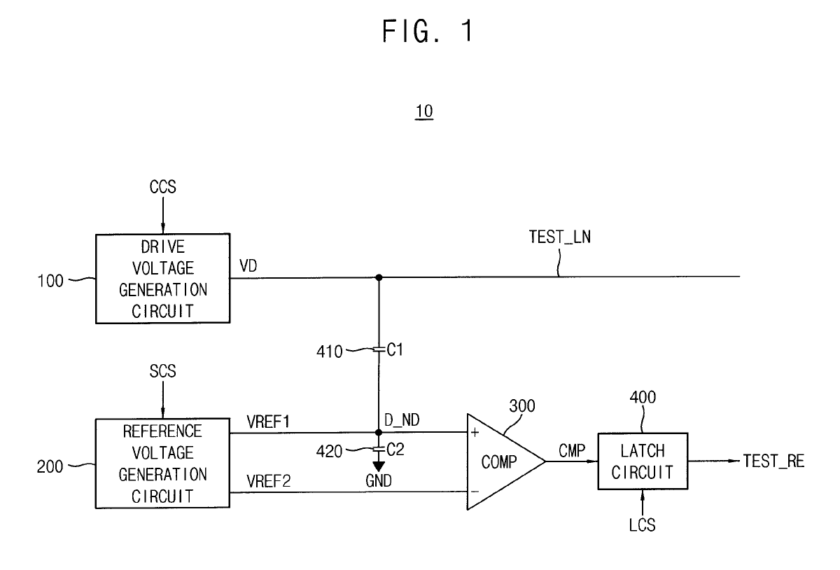

FIG. 1 is a block diagram illustrating a leakage current detection device according to example embodiments.

Referring to FIG. 1, a leakage current detection device 10 includes a drive voltage generation circuit 100, a reference voltage generation circuit 200, a comparator 300, a latch circuit 400, a first capacitor C1 410, and a second capacitor C2 420.

The drive voltage generation circuit 100 provides a drive voltage VD to a test line TEST_LN in response to a charge control signal CCS to charge the test line TEST_LN.

In some example embodiments, when the charge control signal CCS is activated, the drive voltage generation circuit 100 may provide the drive voltage VD to the test line TEST_LN such that the test line TEST_LN is charged. When the charge control signal CCS is deactivated, the drive voltage generation circuit 100 may float the test line TEST_LN.

The test line TEST_LN may correspond to one of multiple drive lines coupled to a memory cell array of a nonvolatile memory device.

In some example embodiments, the test line TEST_LN may correspond to a word line delivering a word line signal to the memory cell array of the nonvolatile memory device.

In some example embodiments, the test line TEST_LN may correspond to a string selection line delivering a string selection signal to the memory cell array of the nonvolatile memory device.

In some example embodiments, the test line TEST_LN may correspond to a ground selection line delivering a ground selection signal to the memory cell array of the nonvolatile memory device.

The reference voltage generation circuit 200 generates a first reference voltage VREF1 and a second reference voltage VREF2.

In some example embodiments, the reference voltage generation circuit 200 may generate the first reference voltage VREF1, and generate the second reference voltage VREF2 by dropping a voltage level of the first reference voltage VREF1.

In other example embodiments, the reference voltage generation circuit 200 may output a ground voltage GND as the first reference voltage VREF1, and generate the second reference voltage VREF2 having a positive voltage.

The reference voltage generation circuit 200 may provide the first reference voltage VREF1 to a detection node D_ND in response to a switch control signal SCS.

In some example embodiments, when the switch control signal SCS is activated, the reference voltage generation circuit 200 may provide the first reference voltage VREF1 to the detection node D_ND to maintain a voltage of the detection node D_ND at the first reference voltage VREF1. When the switch control signal SCS is deactivated, the reference voltage generation circuit 200 may disconnect the first reference voltage VREF1 from the detection node D_ND to float the detection node D_ND.

The first capacitor 410 may be coupled between the test line TEST_LN and the detection node D_ND.

The second capacitor 420 may be coupled between the detection node D_ND and the ground voltage GND.

The comparator 300 outputs a comparison signal CMP by comparing the voltage of the detection node D_ND with the second reference voltage VREF2 provided by the reference voltage generation circuit 200.

In some example embodiments, the comparator 300 may output the comparison signal CMP having a logic low level when the voltage of the detection node D_ND is equal to or higher than the second reference voltage VREF2, and output the comparison signal CMP having a logic high level when the voltage of the detection node D_ND is lower than the second reference voltage VREF2. In another embodiment, the comparator my output the comparison signal having the opposite logic states in response to the same input voltage levels.

The latch circuit 400 latches the comparison signal CMP in response to a latch control signal LCS, and outputs the latched comparison signal as a test result signal TEST_RE, which indicates whether a leakage current flows from the test line TEST_LN.

As described above, the test line TEST_LN may be charged based on the drive voltage VD when the charge control signal CCS is activated. While the test line TEST_LN is charged, the first capacitor 410 and the second capacitor 420 may also be charged. At this time, the detection node D_ND may be maintained at the first reference voltage VREF1 or be floated. After that, when the charge control signal CCS is deactivated, the test line TEST_LN may be floated. In addition, the reference voltage generation circuit 200 may disconnect the first reference voltage VREF1 from the detection node D_ND in response to the switch control signal SCS in a deactivated state, such that the detection node D_ND may be floated. When the test line TEST_LN has a defect such that a leakage current flows from the test line TEST_LN, a voltage of the test line TEST_LN may decrease, and the voltage of the detection node D_ND may also decrease due to a coupling effect caused by the first capacitor 410 and the second capacitor 420. The comparator 300 may output the comparison signal CMP having the logic high level when the voltage of the detection node D_ND is lower than the second reference voltage VREF2. Since the latch circuit 400 latches the comparison signal CMP in response to the latch control signal LCS and outputs the latched comparison signal as the test result signal TEST_RE, the test result signal TEST_RE may indicate whether a leakage current flows from the test line TEST_LN.

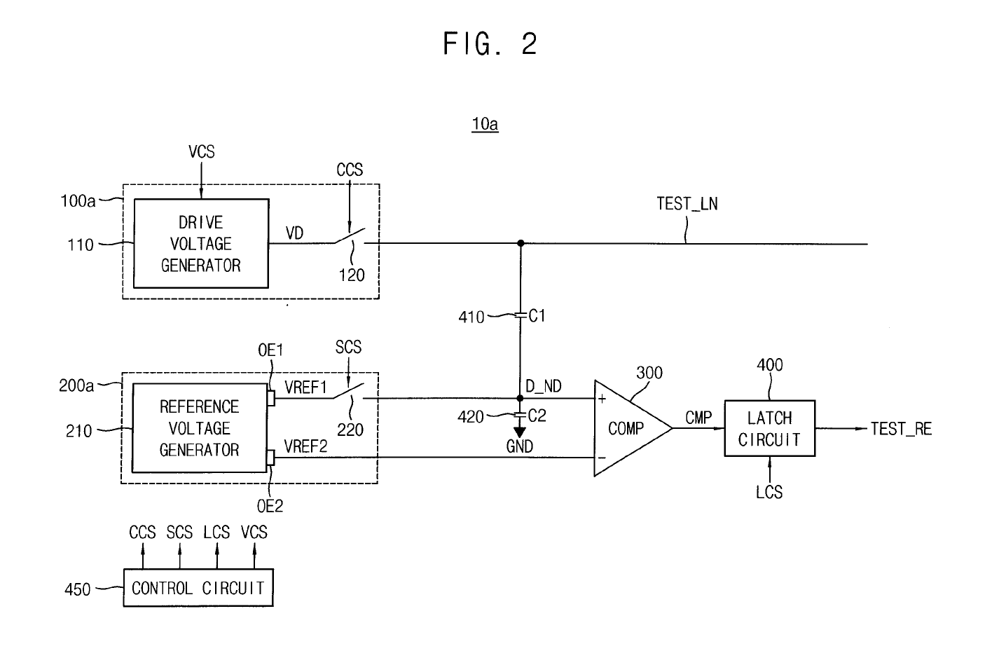

FIG. 2 is a block diagram illustrating an example of a leakage current detection device of FIG. 1.

Referring to FIG. 2, a leakage current detection device 10a may include a drive voltage generation circuit 100a, a reference voltage generation circuit 200a, a comparator 300, a latch circuit 400, a first capacitor 410, and a second capacitor 420.

The comparator 300, the latch circuit 400, the first capacitor 410, and the second capacitor 420 included in the leakage current detection device 10a of FIG. 2 may be the same as the comparator 300, the latch circuit 400, the first capacitor 410, and the second capacitor 420 included in the leakage current detection device 10 of FIG. 1.

The drive voltage generation circuit 100a may include a drive voltage generator 110 and a first switch 120.

The drive voltage generator 110 may generate the drive voltage VD.

The first switch 120 may be coupled between the drive voltage generator 110 and the test line TEST_LN. The first switch 120 may be turned on in response to the charge control signal CCS. For example, when the charge control signal CCS is activated, the first switch 120 may be turned on to provide the drive voltage VD generated by the drive voltage generator 110 to the test line TEST_LN. When the charge control signal CCS is deactivated, the first switch 120 may be turned off to float the test line TEST_LN.

In some example embodiments, the first switch 120 may include an n-type metal oxide semiconductor (NMOS) transistor having a gate on which the charge control signal CCS is applied.

In some example embodiments, the drive voltage generator 110 may adjust a magnitude of the drive voltage VD based on a voltage control signal VCS. For example, the drive voltage generator 110 may adjust the magnitude of the drive voltage VD based on the voltage control signal VCS according to a type of the test line TEST_LN.

For example, when the test line TEST_LN corresponds to a word line of a nonvolatile memory device that delivers a signal having a relatively high voltage, the drive voltage generator 110 may generate the drive voltage VD having a relatively high voltage level based on the voltage control signal VCS. When the test line TEST_LN corresponds to a string selection line or a ground selection line of a nonvolatile memory device that delivers a signal having a relatively low voltage, the drive voltage generator 110 may generate the drive voltage VD having a relatively low voltage level based on the voltage control signal VCS.

Therefore, the drive voltage generator 110 may control a charge level of the test line TEST_LN by adjusting the voltage level of the drive voltage VD.

The reference voltage generation circuit 200a may include a reference voltage generator 210 and a second switch 220.

The reference voltage generator 210 may generate the first reference voltage VREF 1 and output the first reference voltage VREF1 through a first output electrode OE1. The reference voltage generator 210 may generate the second reference voltage VREF2 by dropping a voltage level of the first reference voltage VREF1 and provide the second reference voltage VREF2 to the comparator 300 through a second output electrode OE2.

The second switch 220 may be coupled between the first output electrode OE1 of the reference voltage generator 210 and the detection node D_ND. The second switch 220 may be turned on in response to the switch control signal SCS. For example, when the switch control signal SCS is activated, the second switch 220 may be turned on to provide the first reference voltage VREF1 received from the first output electrode OE1 of the reference voltage generator 210 to the detection node D_ND. When the switch control signal SCS is deactivated, the second switch 220 may be turned off to float the detection node D_ND.

In some example embodiments, the second switch 220 may include an NMOS transistor having a gate on which the switch control signal SCS is applied.

In some example embodiments, the leakage current detection device 10a may further include a control circuit 450 that provides the charge control signal CCS to the first switch 120, provides the voltage control signal VCS to the drive voltage generator 110, provides the switch control signal SCS to the second switch 220, and provides the latch control signal LCS to the latch circuit 400.

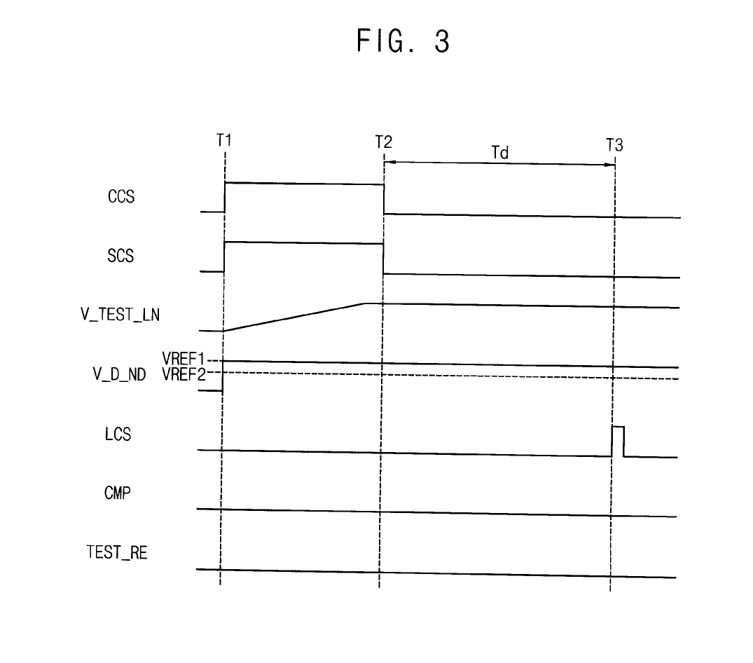

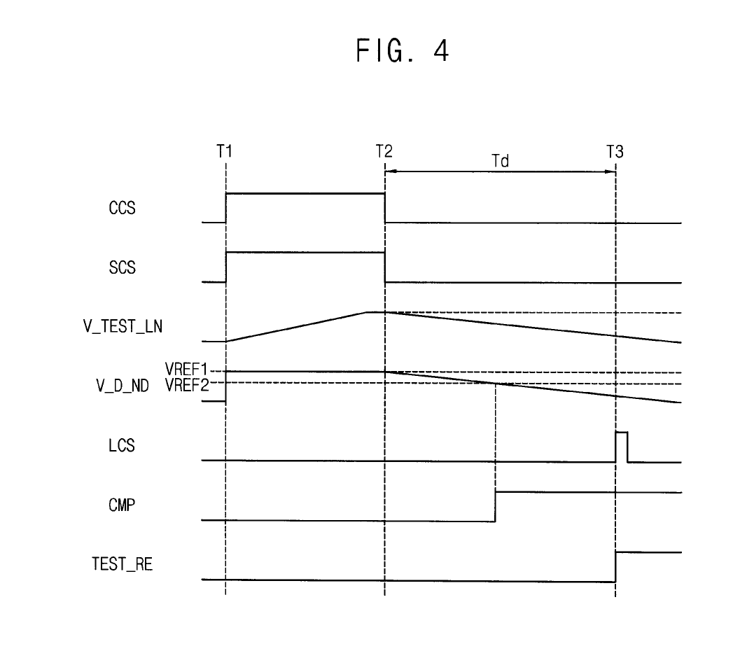

FIGS. 3 and 4 are timing diagrams for describing an operation of the leakage current detection device of FIG. 2.

FIG. 3 illustrates an operation of the leakage current detection device 10a of FIG. 2 when a leakage current does not flow from the test line TEST_LN. FIG. 4 illustrates an operation of the leakage current detection device 10a of FIG. 2 when a leakage current flows from the test line TEST_LN.

Hereinafter, an operation of the leakage current detection device 10a of FIG. 2 in the case that a leakage current does not flow from the test line TEST_LN is described with reference to FIGS. 2 and 3.

Referring to FIGS. 2 and 3, at a first time T1, the control circuit 450 may provide the charge control signal CCS activated at the logic high level to the first switch 120 to turn on the first switch 120, and provide the switch control signal SCS activated at the logic high level to the second switch 220 to turn on the second switch 220.

In FIG. 3, the charge control signal CCS and the switch control signal SCS are illustrated to be activated at the same time. However, example embodiments are not limited thereto. In some example embodiments, the charge control signal CCS and the switch control signal SCS may be activated with a time interval.

Since the second switch 220 is turned on, the voltage V_D_ND of the detection node D_ND may increase to the first reference voltage VREF1.

In addition, since the first switch 120 is turned on, the test line TEST_LN may be charged with charges provided by the drive voltage generator 110 such that a voltage V_TEST_LN of the test line TEST_LN may increase. The voltage V_TEST_LN of the test line TEST_LN may be changed based on the magnitude of the drive voltage VD generated by the drive voltage generator 110.

In some example embodiments, the control circuit 450 may adjust a magnitude of the voltage control signal VCS, and the drive voltage generator 110 may adjust the magnitude of the drive voltage VD based on the magnitude of the voltage control signal VCS.

In some example embodiments, the control circuit 450 may adjust the magnitude of the voltage control signal VCS based on a type of the test line TEST_LN. For example, when the test line TEST_LN corresponds to a word line of a nonvolatile memory device that delivers a signal having a relatively high voltage, the control circuit 450 may increase the magnitude of the voltage control signal VCS. When the test line TEST_LN corresponds to a string selection line or a ground selection line of a nonvolatile memory device that delivers a signal having a relatively low voltage, the control circuit 450 may decrease the magnitude of the voltage control signal VCS.

Therefore, the control circuit 450 may control a charge level of the test line TEST_LN by adjusting the magnitude of the voltage control signal VCS.

At a second time T2, the control circuit 450 may provide the charge control signal CCS deactivated at the logic low level to the first switch 120 to turn off the first switch 120, and provide the switch control signal SCS deactivated at the logic low level to the second switch 220 to turn off the second switch 220.

In FIG. 3, the charge control signal CCS and the switch control signal SCS are illustrated to be deactivated at the same time. However, example embodiments are not limited thereto. In some example embodiments, the charge control signal CCS and the switch control signal SCS may be deactivated with a time interval.

Since the test line TEST_LN is disconnected from the drive voltage VD and the detection node D_ND is disconnected from the first reference voltage VREF1, the test line TEST_LN and the detection node D_ND may be floated.

When a leakage current does not flow from the test line TEST_LN, as illustrated in FIG. 3, the voltage V_TEST_LN of the test line TEST_LN may be maintained without a substantial change after the second time T2. Since the voltage V_TEST_LN of the test line TEST_LN is maintained without a substantial change after the second time T2, the voltage V_D_ND of the detection node D_ND may also be maintained at the first reference voltage VREF1 without a substantial change.

At a third time T3, the control circuit 450 may provide the latch control signal LCS activated at the logic high level to the latch circuit 400. Therefore, the latch circuit 400 may latch the comparison signal CMP output from the comparator 300 at the third time T3, and output the latched comparison signal as the test result signal TEST_RE. The time duration between the second time T2 and the third time T3 may be referred to as a detection time Td.

As illustrated in FIG. 3, when a leakage current does not flow from the test line TEST_LN, the voltage V_D_ND of the detection node D_ND at the third time T3 may correspond to the first reference voltage VREF1, which is higher than the second reference voltage VREF2. Therefore, the comparator 300 may output the comparison signal CMP having the logic low level, and the latch circuit 400 may output the test result signal

TEST_RE having the logic low level.

Hereinafter, an operation of the leakage current detection device 10a of FIG. 2 in the case that a leakage current flows from the test line TEST_LN is described with reference to FIGS. 2 and 4.

Referring to FIGS. 2 and 4, at a first time T1, the control circuit 450 may provide the charge control signal CCS activated at the logic high level to the first switch 120 to turn on the first switch 120, and provide the switch control signal SCS activated at the logic high level to the second switch 220 to turn on the second switch 220.

In FIG. 4, the charge control signal CCS and the switch control signal SCS are illustrated to be activated at the same time. However, example embodiments are not limited thereto. In some example embodiments, the charge control signal CCS and the switch control signal SCS may be activated with a time interval.

Since the second switch 220 is turned on, the voltage V_D_ND of the detection node D_ND may increase to the first reference voltage VREF1.

In addition, since the first switch 120 is turned on, the test line TEST_LN may be charged with charges provided by the drive voltage generator 110 such that the voltage V_TEST_LN of the test line TEST_LN may increase. The voltage V_TEST_LN of the test line TEST_LN may be changed based on the magnitude of the drive voltage VD generated by the drive voltage generator 110.

In some example embodiments, the control circuit 450 may adjust a magnitude of the voltage control signal VCS, and the drive voltage generator 110 may adjust the magnitude of the drive voltage VD based on the magnitude of the voltage control signal VCS.

In some example embodiments, the control circuit 450 may adjust the magnitude of the voltage control signal VCS based on a type of the test line TEST_LN. For example, when the test line TEST_LN corresponds to a word line of a nonvolatile memory device that delivers a signal having a relatively high voltage, the control circuit 450 may increase the magnitude of the voltage control signal VCS. When the test line TEST_LN corresponds to a string selection line or a ground selection line of a nonvolatile memory device that delivers a signal having a relatively low voltage, the control circuit 450 may decrease the magnitude of the voltage control signal VCS.

Therefore, the control circuit 450 may control a charge level of the test line TEST_LN by adjusting the magnitude of the voltage control signal VCS.

At a second time T2, the control circuit 450 may provide the charge control signal CCS deactivated at the logic low level to the first switch 120 to turn off the first switch 120, and provide the switch control signal SCS deactivated at the logic low level to the second switch 220 to turn off the second switch 220.

In FIG. 4, the charge control signal CCS and the switch control signal SCS are illustrated to be deactivated at the same time. However, example embodiments are not limited thereto. In some example embodiments, the charge control signal CCS and the switch control signal SCS may be deactivated with a time interval.

Since the test line TEST_LN is disconnected from the drive voltage VD and the detection node D_ND is disconnected from the first reference voltage VREF1, the test line TEST_LN and the detection node D_ND may be floated.

When the test line TEST_LN has a defect such that a leakage current flows from the test line TEST_LN, as illustrated in FIG. 4, the voltage V_TEST_LN of the test line TEST_LN may decrease based on the leakage current after the second time T2.

Since the test line TEST_LN and the detection node D_ND are floated at the second time T2, as the voltage V_TEST_LN of the test line TEST_LN decreases, the voltage V_D_ND of the detection node D_ND may also decrease due to a coupling effect caused by the first capacitor 410 and the second capacitor 420.

As illustrated in FIG. 4, the comparator 300 may output the comparison signal CMP having the logic high level at a time when the voltage V_D_ND of the detection node D_ND is lower than the second reference voltage VREF2.

At a third time T3, the control circuit 450 may provide the latch control signal LCS activated at the logic high level to the latch circuit 400. Therefore, the latch circuit 400 may latch the comparison signal CMP output from the comparator 300 at the third time T3, and output the latched comparison signal as the test result signal TEST_RE. The time duration between the second time T2 and the third time T3 may be referred to as the detection time Td.

The greater a magnitude of the leakage current flowing from the test line TEST_LN is, the greater a decrease rate of the voltage V_TEST_LN of the test line TEST_LN during the detection time Td. Alternately, the smaller the magnitude of the leakage current flowing from the test line TEST_LN is, the smaller a decrease rate of the voltage V_TEST_LN of the test line TEST_LN during the detection time Td.

When the magnitude of the leakage current flowing from the test line TEST_LN is relatively great, as illustrated in FIG. 4, the voltage V_D_ND of the detection node D_ND may be lower than the second reference voltage VREF2 before the third time T3. In this case, the comparator 300 may output the comparison signal CMP having the logic high level, and the latch circuit 400 may output the test result signal TEST_RE having the logic high level at the third time T3.

On the other hand, when the magnitude of the leakage current flowing from the test line TEST_LN is relatively small, the voltage V_D_ND of the detection node D_ND may be higher than the second reference voltage VREF2 at the third time T3. In this case, the comparator 300 may output the comparison signal CMP having the logic low level, and the latch circuit 400 may output the test result signal TEST_RE having the logic low level at the third time T3.

In some example embodiments, the control circuit 450 may adjust a length of the detection time Td based on a minimum magnitude of the leakage current to be detected. The greater the length of the detection time Td is, the smaller the minimum magnitude of the leakage current that the leakage current detection device 10a is able to detect.

As described above with reference to FIGS. 1 to 4, the leakage current detection device 10 may generate the first reference voltage VREF1, generate the second reference voltage VREF2 by dropping a voltage level of the first reference voltage VREF1, and charge the test line TEST_LN using the drive voltage VD while maintaining the voltage V_D_ND of the detection node D_ND at the first reference voltage VREF1. After that, the leakage current detection device 10 may float the test line TEST_LN and the detection node D_ND. Since the voltage V_D_ND of the detection node D_ND decreases based on the leakage current flowing from the test line TEST_LN, the leakage current detection device 10 may generate the test result signal TEST_RE, which indicates whether the leakage current flows from the test line TEST_LN, by comparing the voltage V_D_ND of the detection node D_ND with the second reference voltage VREF2 after the detection time Td from a time at which the test line TEST_LN and the detection node D_ND are floated.

Therefore, the leakage current detection device 10 according to example embodiments may effectively detect a leakage current flowing from a drive line coupled to a memory cell array of a nonvolatile memory device.

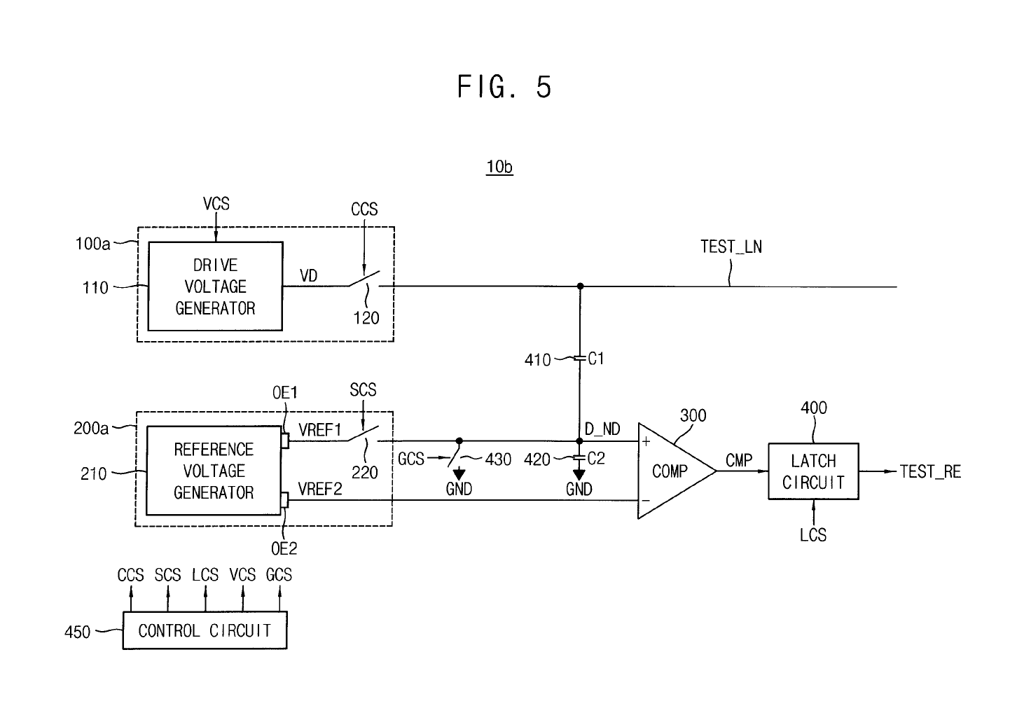

FIG. 5 is a block diagram illustrating an example of a leakage current detection device of FIG. 1.

Referring to FIG. 5, a leakage current detection device 10b may includes a drive voltage generation circuit 100a, a reference voltage generation circuit 200a, a comparator 300, a latch circuit 400, a first capacitor 410, a second capacitor 420, and a third switch 430.

The leakage current detection device 10b of FIG. 5 may be the same as the leakage current detection device 10a of FIG. 2 except that the leakage current detection device 10b of FIG. 5 may further include the third switch 430.

The third switch 430 may be coupled between the detection node D_ND and the ground voltage GND. The third switch 430 may be turned on in response to a ground control signal GCS. For example, when the ground control signal GCS is activated, the third switch 430 may be turned on to couple the detection node D_ND to the ground voltage GND such that the voltage V_D_ND of the detection node D_ND may be kept at the ground voltage GND. When the ground control signal GCS is deactivated, the third switch 430 may be turned off to disconnect the detection node D_ND from the ground voltage GND.

In some example embodiments, the third switch 430 may include an NMOS transistor having a gate on which the ground control signal GCS is applied.

As will be described later, the third switch 430 may be turned on to maintain the voltage V_D_ND of the detection node D_ND at the ground voltage GND after the latch circuit 400 outputs the test result signal TEST_RE in response to the latch control signal LCS.

The ground control signal GCS may be provided by the control circuit 450.

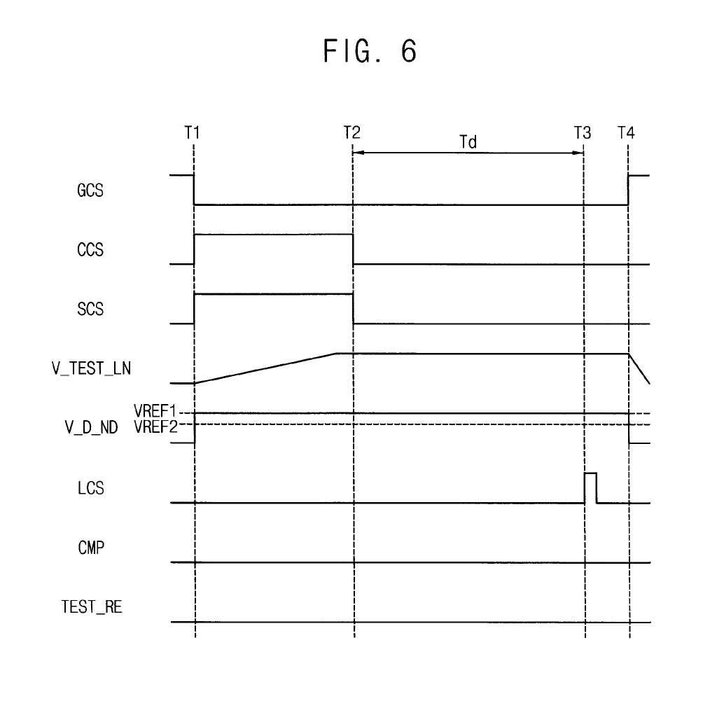

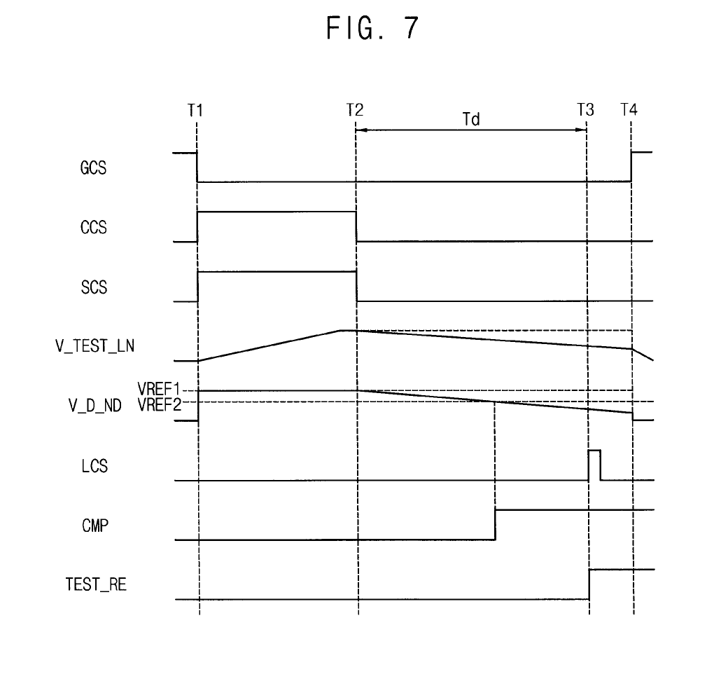

FIGS. 6 and 7 are timing diagrams for describing an operation of the leakage current detection device of FIG. 5.

FIG. 6 illustrates an operation of the leakage current detection device 10b of FIG. 5 when a leakage current does not flow from the test line TEST_LN. FIG. 7 illustrates an operation of the leakage current detection device 10b of FIG. 5 when a leakage current flows from the test line TEST_LN.

Hereinafter, an operation of the leakage current detection device 10b of FIG. 5 in the case that a leakage current does not flow from the test line TEST_LN is described with reference to FIGS. 5 and 6.

Referring to FIGS. 5 and 6, the control circuit 450 may provide the ground control signal GCS activated at the logic high level to the third switch 430 to turn on the third switch 430 before a leakage test operation is started at a first time T1. Therefore, the voltage V_D_ND of the detection node D_ND may be maintained at the ground voltage GND before the leakage test operation is started.

At the first time T1, the control circuit 450 may provide the ground control signal GCS deactivated at the logic low level to the third switch 430 to turn off the third switch 430. In addition, the control circuit 450 may provide the charge control signal CCS activated at the logic high level to the first switch 120 to turn on the first switch 120, and provide the switch control signal SCS activated at the logic high level to the second switch 220 to turn on the second switch 220.

In FIG. 6, the charge control signal CCS and the switch control signal SCS are illustrated to be activated at the same time. However, example embodiments are not limited thereto. In some example embodiments, the charge control signal CCS and the switch control signal SCS may be activated with a time interval.

Since the third switch 430 is turned off and the second switch 220 is turned on, the voltage V_D_ND of the detection node D_ND may increase to the first reference voltage VREF1.

In addition, since the first switch 120 is turned on, the test line TEST_LN may be charged with charges provided by the drive voltage generator 110 such that the voltage V_TEST_LN of the test line TEST_LN may increase. The voltage V_TEST_LN of the test line TEST_LN may be changed based on the magnitude of the drive voltage VD generated by the drive voltage generator 110.

In some example embodiments, the control circuit 450 may adjust a magnitude of the voltage control signal VCS, and the drive voltage generator 110 may adjust the magnitude of the drive voltage VD based on the magnitude of the voltage control signal VCS.

At a second time T2, the control circuit 450 may provide the charge control signal CCS deactivated at the logic low level to the first switch 120 to turn off the first switch 120, and provide the switch control signal SCS deactivated at the logic low level to the second switch 220 to turn off the second switch 220.

In FIG. 6, the charge control signal CCS and the switch control signal SCS are illustrated to be deactivated at the same time. However, example embodiments are not limited thereto. In some example embodiments, the charge control signal CCS and the switch control signal SCS may be deactivated with a time interval.

Since the test line TEST_LN is disconnected from the drive voltage VD and the detection node D_ND is disconnected from the first reference voltage VREF1, the test line TEST_LN and the detection node D_ND may be floated.

When a leakage current does not flow from the test line TEST_LN, as illustrated in FIG. 6, the voltage V_TEST_LN of the test line TEST_LN may be maintained without a substantial change after the second time T2. Since the voltage V_TEST_LN of the test line TEST_LN is maintained without a substantial change after the second time T2, the voltage V_D_ND of the detection node D_ND may also be maintained at the first reference voltage VREF1 without a substantial change.

At a third time T3, the control circuit 450 may provide the latch control signal LCS activated at the logic high level to the latch circuit 400. Therefore, the latch circuit 400 may latch the comparison signal CMP output from the comparator 300 at the third time T3, and output the latched comparison signal as the test result signal TEST_RE. The time duration between the second time T2 and the third time T3 may be referred to as the detection time Td.

As illustrated in FIG. 6, when a leakage current does not flow from the test line TEST_LN, the voltage V_D_ND of the detection node D_ND at the third time T3 may correspond to the first reference voltage VREF1, which is higher than the second reference voltage VREF2. Therefore, the comparator 300 may output the comparison signal CMP having the logic low level, and the latch circuit 400 may output the test result signal TEST_RE having the logic low level.

At a fourth time T4, the control circuit 450 may provide the ground control signal

GCS activated at the logic high level to the third switch 430 to turn on the third switch 430. Therefore, the voltage V_D_ND of the detection node D_ND may become the ground voltage GND and be maintained at the ground voltage GND. The leakage test operation may be finished at the fourth time T4.

Hereinafter, an operation of the leakage current detection device 10b of FIG. 5 in the case that a leakage current flows from the test line TEST_LN is described with reference to FIGS. 5 and 7.

Referring to FIGS. 5 and 7, the control circuit 450 may provide the ground control signal GCS activated at the logic high level to the third switch 430 to turn on the third switch 430 before a leakage test operation is started at a first time T1. Therefore, the voltage V_D_ND of the detection node D_ND may be maintained at the ground voltage GND before the leakage test operation is started.

At the first time T1, the control circuit 450 may provide the ground control signal GCS deactivated at the logic low level to the third switch 430 to turn off the third switch 430. In addition, the control circuit 450 may provide the charge control signal CCS activated at the logic high level to the first switch 120 to turn on the first switch 120, and provide the switch control signal SCS activated at the logic high level to the second switch 220 to turn on the second switch 220.

In FIG. 7, the charge control signal CCS and the switch control signal SCS are illustrated to be activated at the same time. However, example embodiments are not limited thereto. In some example embodiments, the charge control signal CCS and the switch control signal SCS may be activated with a time interval.

Since the third switch 430 is turned off and the second switch 220 is turned on, the voltage V_D_ND of the detection node D_ND may increase to the first reference voltage VREF1.

In addition, since the first switch 120 is turned on, the test line TEST_LN may be charged with charges provided by the drive voltage generator 110 such that the voltage V_TEST_LN of the test line TEST_LN may increase. The voltage V_TEST_LN of the test line TEST_LN may be changed based on the magnitude of the drive voltage VD generated by the drive voltage generator 110.

In some example embodiments, the control circuit 450 may adjust a magnitude of the voltage control signal VCS, and the drive voltage generator 110 may adjust the magnitude of the drive voltage VD based on the magnitude of the voltage control signal VCS.

At a second time T2, the control circuit 450 may provide the charge control signal CCS deactivated at the logic low level to the first switch 120 to turn off the first switch 120, and provide the switch control signal SCS deactivated at the logic low level to the second switch 220 to turn off the second switch 220.

In FIG. 7, the charge control signal CCS and the switch control signal SCS are illustrated to be deactivated at the same time. However, example embodiments are not limited thereto. In some example embodiments, the charge control signal CCS and the switch control signal SCS may be deactivated with a time interval.

Since the test line TEST_LN is disconnected from the drive voltage VD and the detection node D_ND is disconnected from the first reference voltage VREF1, the test line TEST_LN and the detection node D_ND may be floated.

When the test line TEST_LN has a defect such that a leakage current flows from the test line TEST_LN, as illustrated in FIG. 7, the voltage V_TEST_LN of the test line TEST_LN may decrease based on the leakage current after the second time T2.

Since the test line TEST_LN and the detection node D_ND are floated at the second time T2, as the voltage V_TEST_LN of the test line TEST_LN decreases, the voltage V_D_ND of the detection node D_ND may also decrease due to a coupling effect caused by the first capacitor 410 and the second capacitor 420.

As illustrated in FIG. 7, the comparator 300 may output the comparison signal CMP having the logic high level at a time when the voltage V_D_ND of the detection node D_ND is lower than the second reference voltage VREF2.

At a third time T3, the control circuit 450 may provide the latch control signal LCS activated at the logic high level to the latch circuit 400. Therefore, the latch circuit 400 may latch the comparison signal CMP output from the comparator 300 at the third time T3, and output the latched comparison signal as the test result signal TEST_RE. The time duration between the second time T2 and the third time T3 may be referred to as the detection time Td.

The greater a magnitude of the leakage current flowing from the test line TEST_LN is, the greater a decrease rate of the voltage V_TEST_LN of the test line TEST_LN during the detection time Td. Alternately, the smaller the magnitude of the leakage current flowing from the test line TEST_LN is, the smaller a decrease rate of the voltage V_TEST_LN of the test line TEST_LN during the detection time Td.

When the magnitude of the leakage current flowing from the test line TEST_LN is relatively great, as illustrated in FIG. 7, the voltage V_D_ND of the detection node D_ND may be lower than the second reference voltage VREF2 before the third time T3. In this case, the comparator 300 may output the comparison signal CMP having the logic high level, and the latch circuit 400 may output the test result signal TEST_RE having the logic high level at the third time T3.

On the other hand, when the magnitude of the leakage current flowing from the test line TEST_LN is relatively small, the voltage V_D_ND of the detection node D_ND may be higher than the second reference voltage VREF2 at the third time T3. In this case, the comparator 300 may output the comparison signal CMP having the logic low level, and the latch circuit 400 may output the test result signal TEST_RE having the logic low level at the third time T3.

In some example embodiments, the control circuit 450 may adjust a length of the detection time Td based on a minimum magnitude of the leakage current to be detected. The greater the length of the detection time Td is, the smaller the minimum magnitude of the leakage current that the leakage current detection device 10a is able to detect.

At a fourth time T4, the control circuit 450 may provide the ground control signal GCS activated at the logic high level to the third switch 430 to turn on the third switch 430. Therefore, the voltage V_D_ND of the detection node D_ND may become the ground voltage GND and be maintained at the ground voltage GND. The leakage test operation may be finished at the fourth time T4.

Generally, a signal having a relatively high voltage may be applied to a word line of a nonvolatile memory device when a program operation is performed. Therefore, when the test line TEST_LN is coupled to a word line of a nonvolatile memory device, the voltage V_TEST_LN of the test line TEST_LN may become relatively high during a program operation.

Since the leakage current detection device 10b of FIG. 5 includes the third switch 430 that is turned on after finishing the leakage test operation, the voltage V_D_ND of the detection node D_ND may be maintained at the ground voltage GND without increasing to a high voltage although a signal having a relatively high voltage is applied to the test line TEST_LN during the program operation. Therefore, the comparator 300, which is coupled to the detection node D_ND, may be implemented using elements operating in a low voltage range.

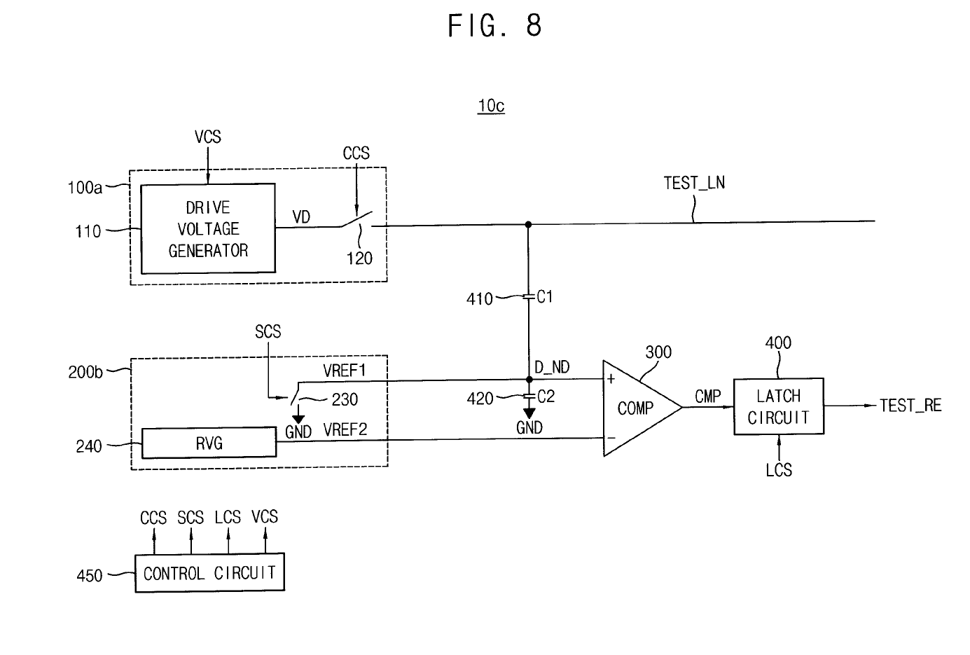

FIG. 8 is a block diagram illustrating an example of a leakage current detection device of FIG. 1.

Referring to FIG. 8, a leakage current detection device 10c may include a drive voltage generation circuit 100a, a reference voltage generation circuit 200b, a comparator 300, a latch circuit 400, a first capacitor 410, and a second capacitor 420.

The drive voltage generation circuit 100a, the comparator 300, the latch circuit 400, the first capacitor 410, and the second capacitor 420 included in the leakage current detection device 10c of FIG. 8 may be the same as the drive voltage generation circuit 100a, the comparator 300, the latch circuit 400, the first capacitor 410, and the second capacitor 420 included in the leakage current detection device 10a of FIG. 2.

The reference voltage generation circuit 200b may include a fourth switch 230 and a reference voltage generator RVG 240.

The fourth switch 230 may be coupled between the detection node D_ND and the ground voltage GND. The fourth switch 230 may be turned on in response to the switch control signal SCS. For example, when the switch control signal SCS is activated, the fourth switch 230 may be turned on to provide the ground voltage GND to the detection node D_ND as the first reference voltage VREF1. When the switch control signal SCS is deactivated, the fourth switch 230 may be turned off to float the detection node D_ND.

In some example embodiments, the fourth switch 230 may include an NMOS transistor having a gate on which the switch control signal SCS is applied.

The reference voltage generator 240 may generate the second reference voltage VREF2 and provide the second reference voltage VREF2 to the comparator 300. In some example embodiments, the second reference voltage VREF2 generated by the reference voltage generator 240 may be a positive voltage.

In some example embodiments, the leakage current detection device 10c may further include a control circuit 450 that provides the charge control signal CCS to the first switch 120, provides the voltage control signal VCS to the drive voltage generator 110, provides the switch control signal SCS to the fourth switch 230, and provides the latch control signal LCS to the latch circuit 400.

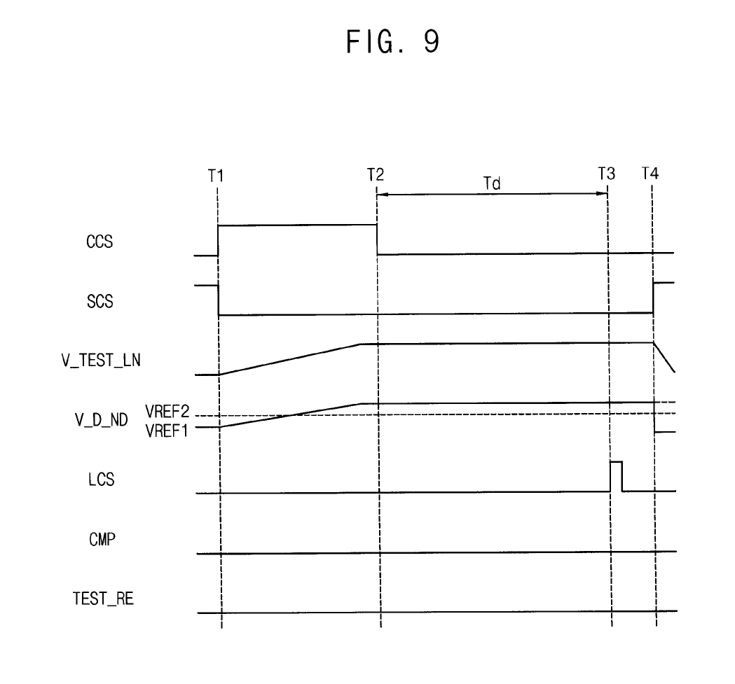

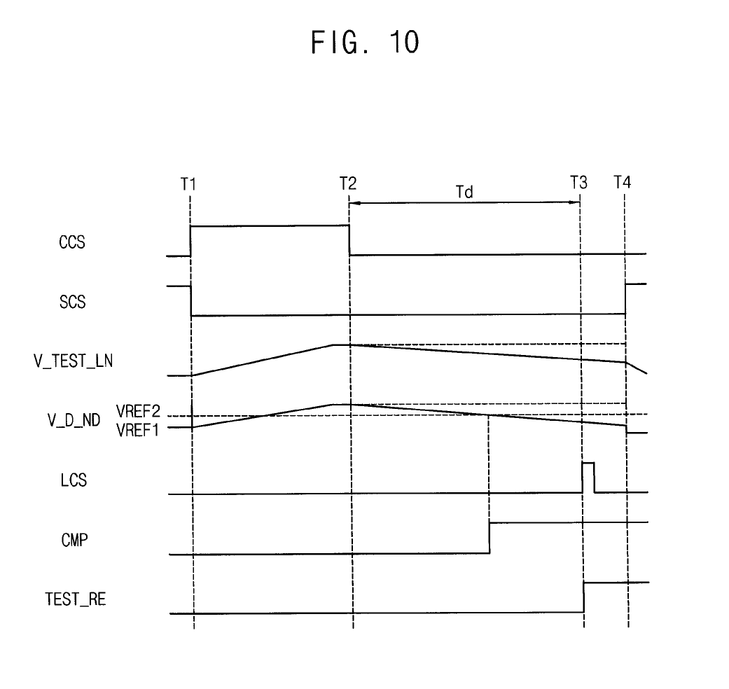

FIGS. 9 and 10 are timing diagrams for describing an operation of the leakage current detection device of FIG. 8.

FIG. 9 illustrates an operation of the leakage current detection device 10c of FIG. 8 when a leakage current does not flow from the test line TEST_LN. FIG. 10 illustrates an operation of the leakage current detection device 10c of FIG. 8 when a leakage current flows from the test line TEST_LN.

Hereinafter, an operation of the leakage current detection device 10c of FIG. 8 in the case that a leakage current does not flow from the test line TEST_LN is described with reference to FIGS. 8 and 9.

Referring to FIGS. 8 and 9, the control circuit 450 may provide the switch control signal SCS activated at the logic high level to the fourth switch 230 to turn on the fourth switch 230 before a leakage test operation is started at a first time T1. Therefore, the voltage V_D_ND of the detection node D_ND may be maintained at the ground voltage GND before the leakage test operation is started.

At the first time T1, the control circuit 450 may provide the switch control signal SCS deactivated at the logic low level to the fourth switch 230 to turn off the fourth switch 230. In addition, the control circuit 450 may provide the charge control signal CCS activated at the logic high level to the first switch 120 to turn on the first switch 120.

In FIG. 9, the charge control signal CCS and the switch control signal SCS are illustrated to transit a logic level at the same time. However, example embodiments are not limited thereto. In some example embodiments, the charge control signal CCS and the switch control signal SCS may transit a logic level with a time interval.

Since the fourth switch 230 is turned off, the detection node D_ND may be floated.

In addition, since the first switch 120 is turned on, the test line TEST_LN may be charged with charges provided by the drive voltage generator 110 such that the voltage V_TEST_LN of the test line TEST_LN may increase. The voltage V_TEST_LN of the test line TEST_LN may be changed based on the magnitude of the drive voltage VD generated by the drive voltage generator 110.

In some example embodiments, the control circuit 450 may adjust a magnitude of the voltage control signal VCS, and the drive voltage generator 110 may adjust the magnitude of the drive voltage VD based on the magnitude of the voltage control signal VCS.

As illustrated in FIG. 9, since the detection node D_ND is floated, as the voltage V_TEST_LN of the test line TEST_LN increases, the voltage V_D_ND of the detection node D_ND may also increase due to a coupling effect caused by the first capacitor 410 and the second capacitor 420. An increase rate of the V_D_ND of the detection node D_ND may be determined based on a capacitance of the first capacitor 410 and a capacitance of the second capacitor 420. For example, the voltage V_D_ND of the detection node D_ND may be (C1/(C1+C2)) times of the voltage V_TEST_LN of the test line TEST_LN when the voltage V_TEST_LN of the test line TEST_LN is stabilized. The capacitance of the first capacitor 410 and the capacitance of the second capacitor 420 may be determined such that the voltage V_D_ND of the detection node D_ND may be higher than the second reference voltage VREF2 after the voltage V_TEST_LN of the test line TEST_LN is stabilized.

At a second time T2, the control circuit 450 may provide the charge control signal CCS deactivated at the logic low level to the first switch 120 to turn off the first switch 120. Therefore, the test line TEST_LN may be floated.

As described above, the detection node D_ND has been floated since the first time T1.

When a leakage current does not flow from the test line TEST_LN, as illustrated in FIG. 9, the voltage V_TEST_LN of the test line TEST_LN may be maintained without a substantial change after the second time T2. Since the voltage V_TEST_LN of the test line TEST_LN is maintained without a substantial change after the second time T2, the voltage V_D_ND of the detection node D_ND may also be maintained without a substantial change.

At a third time T3, the control circuit 450 may provide the latch control signal LCS activated at the logic high level to the latch circuit 400. Therefore, the latch circuit 400 may latch the comparison signal CMP output from the comparator 300 at the third time T3, and output the latched comparison signal as the test result signal TEST_RE. The time duration between the second time T2 and the third time T3 may be referred to as the detection time Td.

As illustrated in FIG. 9, when a leakage current does not flow from the test line TEST_LN, the voltage V_D_ND of the detection node D_ND at the third time T3 may be higher than the second reference voltage VREF2. Therefore, the comparator 300 may output the comparison signal CMP having the logic low level, and the latch circuit 400 may output the test result signal TEST_RE having the logic low level.

At a fourth time T4, the control circuit 450 may provide the switch control signal SCS activated at the logic high level to the fourth switch 230 to turn on the fourth switch 230. Therefore, the voltage V_D_ND of the detection node D_ND, which is the first reference voltage VREF1, will correspond to the ground voltage GND, and be maintained at the ground voltage GND. The leakage test operation may be finished at the fourth time T4.

Hereinafter, an operation of the leakage current detection device 10c of FIG. 8 in the case that a leakage current flows from the test line TEST_LN is described with reference to FIGS. 8 and 10.

Referring to FIGS. 8 and 10, the control circuit 450 may provide the switch control signal SCS activated at the logic high level to the fourth switch 230 to turn on the fourth switch 230 before a leakage test operation is started at a first time T1. Therefore, the voltage V_D_ND of the detection node D_ND may be maintained at the ground voltage GND before the leakage test operation is started.

At the first time T1, the control circuit 450 may provide the switch control signal SCS deactivated at the logic low level to the fourth switch 230 to turn off the fourth switch 230. In addition, the control circuit 450 may provide the charge control signal CCS activated at the logic high level to the first switch 120 to turn on the first switch 120.

In FIG. 10, the charge control signal CCS and the switch control signal SCS are illustrated to transit a logic level at the same time. However, example embodiments are not limited thereto. In some example embodiments, the charge control signal CCS and the switch control signal SCS may transit a logic level with a time interval.

Since the fourth switch 230 is turned off, the detection node D_ND may be floated.

In addition, since the first switch 120 is turned on, the test line TEST_LN may be charged with charges provided by the drive voltage generator 110 such that the voltage V_TEST_LN of the test line TEST_LN may increase. The voltage V_TEST_LN of the test line TEST_LN may be changed based on the magnitude of the drive voltage VD generated by the drive voltage generator 110.

In some example embodiments, the control circuit 450 may adjust a magnitude of the voltage control signal VCS, and the drive voltage generator 110 may adjust the magnitude of the drive voltage VD based on the magnitude of the voltage control signal VCS.

As illustrated in FIG. 10, since the detection node D_ND is floated, as the voltage V_TEST_LN of the test line TEST_LN increases, the voltage V_D_ND of the detection node D_ND may also increase due to a coupling effect caused by the first capacitor 410 and the second capacitor 420. An increase rate of the V_D_ND of the detection node D_ND may be determined based on a capacitance of the first capacitor 410 and a capacitance of the second capacitor 420. For example, the voltage V_D_ND of the detection node D_ND may be (C1/(C1+C2)) times of the voltage V_TEST_LN of the test line TEST_LN when the voltage V_TEST_LN of the test line TEST_LN is stabilized. The capacitance of the first capacitor 410 and the capacitance of the second capacitor 420 may be determined such that the voltage V_D_ND of the detection node D_ND may be higher than the second reference voltage VREF2 after the voltage V_TEST_LN of the test line TEST_LN is stabilized.

At a second time T2, the control circuit 450 may provide the charge control signal CCS deactivated at the logic low level to the first switch 120 to turn off the first switch 120. Therefore, the test line TEST_LN may be floated.

As described above, the detection node D_ND has been floated since the first time T1.

When the test line TEST_LN has a defect such that a leakage current flows from the test line TEST_LN, as illustrated in FIG. 10, the voltage V_TEST_LN of the test line TEST_LN may decrease based on the leakage current after the second time T2.

Since the test line TEST_LN and the detection node D_ND have been floated, as the voltage V_TEST_LN of the test line TEST_LN decreases, the voltage V_D_ND of the detection node D_ND may also decrease due to a coupling effect caused by the first capacitor 410 and the second capacitor 420.

As illustrated in FIG. 10, the comparator 300 may output the comparison signal CMP having the logic high level at a time when the voltage V_D_ND of the detection node D_ND is lower than the second reference voltage VREF2.

At a third time T3, the control circuit 450 may provide the latch control signal LCS activated at the logic high level to the latch circuit 400. Therefore, the latch circuit 400 may latch the comparison signal CMP output from the comparator 300 at the third time T3, and output the latched comparison signal as the test result signal TEST_RE. The time duration between the second time T2 and the third time T3 may be referred to as the detection time Td.

The greater a magnitude of the leakage current flowing from the test line TEST_LN is, the greater a decrease rate of the voltage V_TEST_LN of the test line TEST_LN during the detection time Td. Alternately, the smaller the magnitude of the leakage current flowing from the test line TEST_LN is, the smaller a decrease rate of the voltage V_TEST_LN of the test line TEST_LN during the detection time Td.

When the magnitude of the leakage current flowing from the test line TEST_LN is relatively great, as illustrated in FIG. 10, the voltage V_D_ND of the detection node D_ND may be lower than the second reference voltage VREF2 before the third time T3. In this case, the comparator 300 may output the comparison signal CMP having the logic high level, and the latch circuit 400 may output the test result signal TEST_RE having the logic high level at the third time T3.

On the other hand, when the magnitude of the leakage current flowing from the test line TEST_LN is relatively small, the voltage V_D_ND of the detection node D_ND may be higher than the second reference voltage VREF2 at the third time T3. In this case, the comparator 300 may output the comparison signal CMP having the logic low level, and the latch circuit 400 may output the test result signal TEST_RE having the logic low level at the third time T3.

In some example embodiments, the control circuit 450 may adjust a length of the detection time Td based on a minimum magnitude of the leakage current to be detected. The greater the length of the detection time Td is, the smaller the minimum magnitude of the leakage current that the leakage current detection device 10a is able to detect.

At a fourth time T4, the control circuit 450 may provide the switch control signal SCS activated at the logic high level to the fourth switch 230 to turn on the fourth switch 230. Therefore, the voltage V_D_ND of the detection node D_ND may become the ground voltage GND and be maintained at the ground voltage GND. The leakage test operation may be finished at the fourth time T4.

Generally, a signal having a relatively high voltage may be applied to a word line of a nonvolatile memory device when a program operation is performed. Therefore, when the test line TEST_LN is coupled to a word line of a nonvolatile memory device, the voltage V_TEST_LN of the test line TEST_LN may become relatively high during a program operation.

Since the leakage current detection device 10c of FIG. 8 includes the fourth switch 230 that is turned on after finishing the leakage test operation, the voltage V_D_ND of the detection node D_ND may be maintained at the ground voltage GND without increasing to a high voltage although a signal having a relatively high voltage is applied to the test line TEST_LN during the program operation. Therefore, the comparator 300, which is coupled to the detection node D_ND, may be implemented using elements operating in a low voltage range.

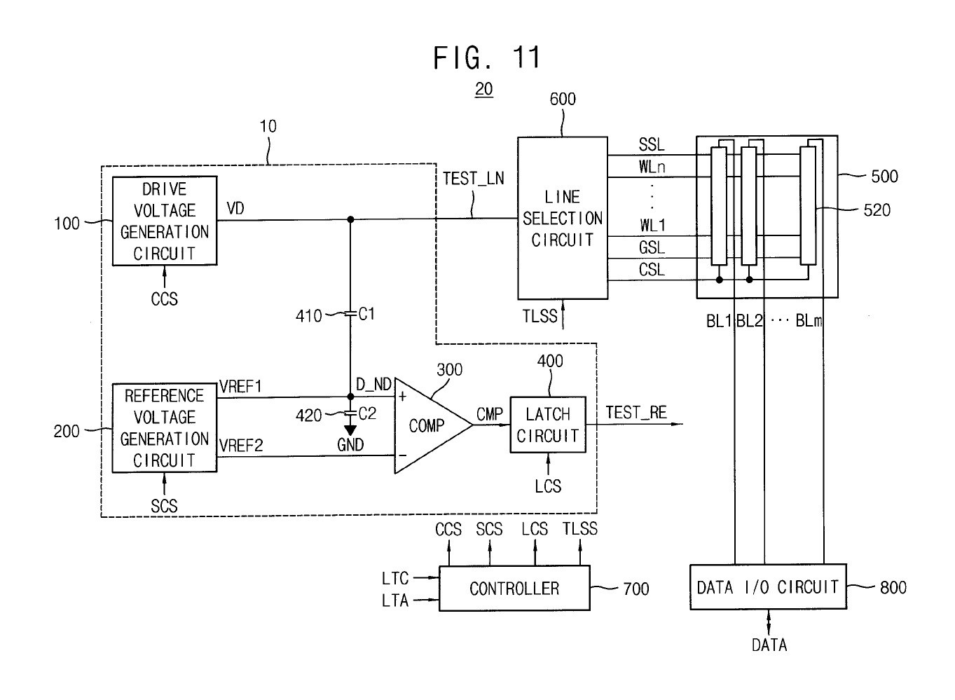

FIG. 11 is a block diagram illustrating a nonvolatile memory device according to example embodiments.

Referring to FIG. 11, a nonvolatile memory device 20 includes a memory cell array 500, a line selection circuit 600, a controller 700, a data input/output (I/O) circuit 800, and a leakage current detection device 10.

The memory cell array 500 may include a plurality of memory cell strings 520.

The plurality of memory cell strings 520 may be coupled to the line selection circuit 600 through a plurality of drive lines. For example, the plurality of memory cell strings 520 may be coupled to the line selection circuit 600 through a string selection line SSL, a plurality of word lines WL1 to WLn, a ground selection line GSL, and a common source line CSL. In addition, the plurality of memory cell strings 520 may be coupled to the data I/O circuit 800 through a plurality of bit lines BL1 to BLm. Here, n and m represent positive integers.

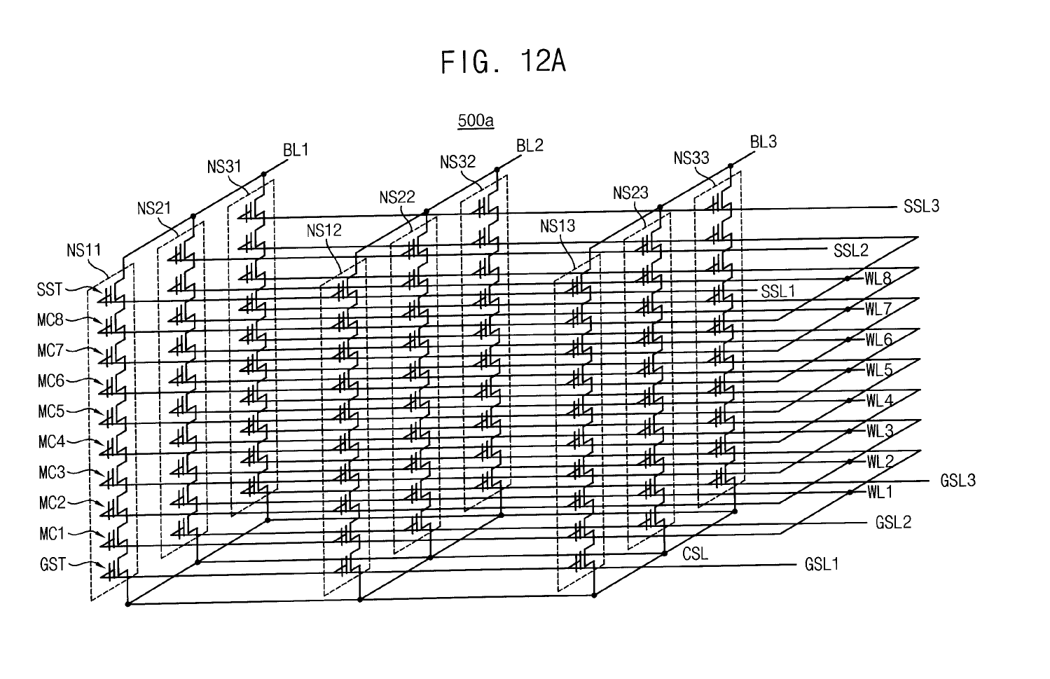

FIGS. 12A and 12B are circuit diagrams illustrating examples of a memory cell array included in the nonvolatile memory device of FIG. 11.

A memory cell array 500a of FIG. 12A may be formed on a substrate in a three-dimensional structure (or vertical structure). For example, the plurality of memory cell strings 520 included in the memory cell array 500a may be formed perpendicular to the substrate.

Referring to FIG. 12A, the memory cell array 500a may include memory cell strings NS11 to NS33 coupled between bit lines BL1, BL2 and BL3 and the common source line CSL.

Each of the memory cell strings NS11 to NS33 may include a string selection transistor SST, a plurality of memory cells MC1 to MC8, and a ground selection transistor GST.

In FIG. 12A, each of the memory cell strings NS11 to NS33 is illustrated to include eight memory cells MC1 to MC8. However, example embodiments are not limited thereto. In some example embodiments, each of the memory cell strings NS11 to NS33 may include any number of memory cells.

The string selection transistor SST may be connected to corresponding string selection lines SSL1 to SSL3. The plurality of memory cells MC1 to MC8 may be connected to corresponding word lines WL1 to WL8, respectively. The ground selection transistor GST may be connected to corresponding ground selection lines GSL1 to GSL3. The string selection transistor SST may be connected to corresponding bit lines BL1, BL2 and BL3, and the ground selection transistor GST may be connected to the common source line CSL.

Word lines (e.g., WL1) having the same height may be commonly connected, and the ground selection lines GSL1 to GSL3 and the string selection lines SSL1 to SSL3 may be separated.

A memory cell array 500b of FIG. 12B may be formed on a substrate in a two-dimensional structure (or horizontal structure). For example, the plurality of memory cell strings 520 included in the memory cell array 500b may be formed parallel to the substrate.

Referring to FIG. 12B, the memory cell array 500b may include memory cell strings NS1 to NSm.

Each of the memory cell strings NS 1 to NSm may include a string selection transistor SST, a plurality of memory cells MC, and a ground selection transistor GST that are serially connected to each other.

The string selection transistor SST included in each of the memory cell strings NS1 to NSm may be commonly connected to the string selection line SSL. Memory cells arranged in the same row may be commonly connected to corresponding word lines WL1 to WLn. The ground selection transistor GST included in each of the memory cell strings NS 1 to NSm may be commonly connected to the ground selection line GSL.

The ground selection transistors GST included in the memory cell strings NS1 to NSm may be commonly connected to the common source line CSL.

The string selection transistor SST included in each of the memory cell strings NS1 to NSm may be connected to corresponding bit lines BL1 to BLm.

Referring again to FIG. 11, the data I/O circuit 800 may be coupled to the memory cell array 500 through the plurality of bit lines BL1 to BLm. The data I/O circuit 800 may output data DATA read from the memory cells MC through the plurality of bit lines BL1 to BLm to an external device, and write data DATA received from the external device in the memory cells MC through the plurality of bit lines BL1 to BLm.

In some example embodiments, the data I/O circuit 800 may include a sense amplifier, a page buffer, a column selection circuit, a write driver, a data buffer, etc.

The line selection circuit 600 may be coupled to the plurality of memory cell strings 520 included in the memory cell array 500 through the string selection line SSL, the plurality of word lines WL1 to WLn, the ground selection line GSL, and the common source line CSL.

The line selection circuit 600 may receive a test line selection signal TLSS from the controller 700. The line selection circuit 600 may connect a test line TEST_LN to one of the string selection line SSL, the plurality of word lines WL1 to WLn, and the ground selection line GSL based on the test line selection signal TLSS.

In some example embodiments, the controller 700 may receive a leakage test command LTC and a leakage test address LTA from outside. The controller 700 may generate a charge control signal CCS, a switch control signal SCS, and a latch control signal LCS based on the leakage test command LTC, and generate the test line selection signal TLSS based on the leakage test address LTA.

For example, the controller 700 may generate the test line selection signal TLSS indicating one of the string selection line SSL, the plurality of word lines WL1 to WLn, and the ground selection line GSL that is represented by the leakage test address LTA.

The leakage current detection device 10 generates a test result signal TEST_RE by testing whether a leakage current flows from the test line TEST_LN based on the charge control signal CCS, the switch control signal SCS, and the latch control signal LCS.

The leakage current detection device 10 may include a drive voltage generation circuit 100, a reference voltage generation circuit 200, a comparator 300, a latch circuit 400, a first capacitor C1 410, and a second capacitor C2 420.

The drive voltage generation circuit 100 may provide a drive voltage VD to the test line TEST_LN in response to the charge control signal CCS to charge the test line TEST_LN.

In some example embodiments, when the charge control signal CCS is activated, the drive voltage generation circuit 100 may provide the drive voltage VD to the test line TEST_LN such that the test line TEST_LN is charged. When the charge control signal CCS is deactivated, the drive voltage generation circuit 100 may float the test line TEST_LN.

As described above, the test line TEST_LN may be coupled to one of the string selection line SSL, the plurality of word lines WL1 to WLn, and the ground selection line GSL.

The reference voltage generation circuit 200 may generate a first reference voltage VREF1 and a second reference voltage VREF2.

In some example embodiments, the reference voltage generation circuit 200 may generate the first reference voltage VREF1, and generate the second reference voltage VREF2 by dropping a voltage level of the first reference voltage VREF1.

In other example embodiments, the reference voltage generation circuit 200 may output a ground voltage GND as the first reference voltage VREF1, and generate the second reference voltage VREF2 having a positive voltage.

The reference voltage generation circuit 200 may provide the first reference voltage VREF1 to a detection node D_ND in response to the switch control signal SCS.

In some example embodiments, when the switch control signal SCS is activated, the reference voltage generation circuit 200 may provide the first reference voltage VREF1 to the detection node D_ND to maintain a voltage of the detection node D_ND at the first reference voltage VREF1. When the switch control signal SCS is deactivated, the reference voltage generation circuit 200 may disconnect the first reference voltage VREF1 from the detection node D_ND to float the detection node D_ND.

The first capacitor 410 may be coupled between the test line TEST_LN and the detection node D_ND.

The second capacitor 420 may be coupled between the detection node D_ND and the ground voltage GND.

The comparator 300 may output a comparison signal CMP by comparing the voltage of the detection node D_ND with the second reference voltage VREF2 provided by the reference voltage generation circuit 200.

In some example embodiments, the comparator 300 may output the comparison signal CMP having a logic low level when the voltage of the detection node D_ND is equal to or higher than the second reference voltage VREF2, and output the comparison signal CMP having a logic high level when the voltage of the detection node D_ND is lower than the second reference voltage VREF2.

The latch circuit 400 may latch the comparison signal CMP in response to the latch control signal LCS, and output the latched comparison signal as the test result signal TEST_RE. Therefore, the test result signal TEST_RE may indicate whether a leakage current flows from a drive line among the string selection line SSL, the plurality of word lines WL1 to WLn, and the ground selection line GSL, which is coupled to the test line TEST_LN.

In some example embodiments, the leakage current detection device 10 included in the nonvolatile memory device 20 of FIG. 11 may be implemented as one of the leakage current detection device 10a of FIG. 2, the leakage current detection device 10b of FIG. 5, and the leakage current detection device 10c of FIG. 8.

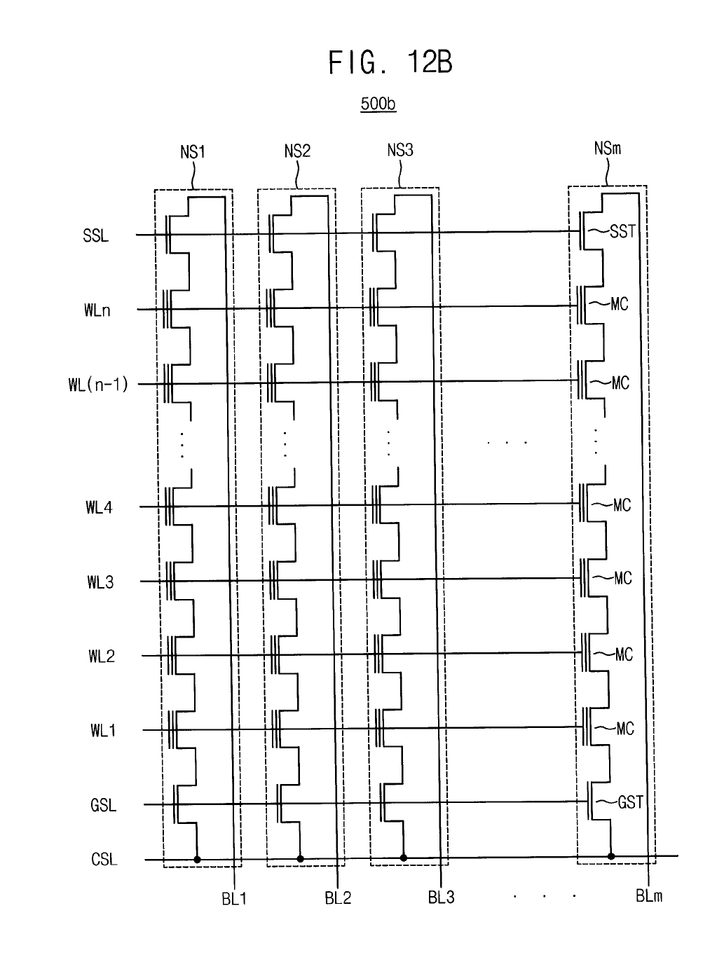

FIG. 13 is a block diagram illustrating an example of a nonvolatile memory device of FIG. 11.

Referring to FIG. 13, a nonvolatile memory device 20a may include a memory cell array 500, a line selection circuit 600, a controller 700, a data I/O circuit 800, a drive voltage generation circuit 100a, a reference voltage generation circuit 200a, a comparator 300, a latch circuit 400, a first capacitor 410, and a second capacitor 420.

The memory cell array 500, the line selection circuit 600, and the data I/O circuit 800 included in the nonvolatile memory device 20a of FIG. 13 may be the same as the memory cell array 500, the line selection circuit 600, and the data I/O circuit 800 included in the nonvolatile memory device 20 of FIG. 11. In addition, the controller 700 included in the nonvolatile memory device 20a of FIG. 13 may be the same as the controller 700 included in the nonvolatile memory device 20 of FIG. 11 except that the controller 700 included in the nonvolatile memory device 20a of FIG. 13 further generates a voltage control signal VCS.

The drive voltage generation circuit 100a included in the nonvolatile memory device 20a may include a drive voltage generator 110 and a first switch 120.

The drive voltage generator 110 may generate the drive voltage VD.

The first switch 120 may be coupled between the drive voltage generator 110 and the test line TEST_LN. The first switch 120 may be turned on in response to the charge control signal CCS. For example, when the charge control signal CCS is activated, the first switch 120 may be turned on to provide the drive voltage VD generated by the drive voltage generator 110 to the test line TEST_LN. When the charge control signal CCS is deactivated, the first switch 120 may be turned off to float the test line TEST_LN.

In some example embodiments, the drive voltage generator 110 may adjust a magnitude of the drive voltage VD based on the voltage control signal VCS received from the controller 700.

In some example embodiments, the controller 700 may adjust a magnitude of the voltage control signal VCS based on a type of a drive line to which the test line TEST_LN is coupled. For example, when one of the plurality of word lines WL1 to WLn, which deliver a signal having a relatively high voltage to the memory cell array 500, is coupled to the test line TEST_LN, the controller 700 may increase the magnitude of the voltage control signal VCS. When one of the string selection line SSL and the ground selection line GSL, which deliver a signal having a relatively low voltage to the memory cell array 500, is coupled to the test line TEST_LN, the controller 700 may decrease the magnitude of the voltage control signal VCS.

Therefore, the controller 700 may control a charge level of the test line TEST_LN by adjusting the magnitude of the voltage control signal VCS.

The reference voltage generation circuit 200a included in the nonvolatile memory device 20a may include a reference voltage generator 210 and a second switch 220.

The reference voltage generator 210 may generate the first reference voltage VREF1 and output the first reference voltage VREF1 through a first output electrode OE1. The reference voltage generator 210 may generate the second reference voltage VREF2 by dropping a voltage level of the first reference voltage VREF1 and provide the second reference voltage VREF2 to the comparator 300 through a second output electrode OE2.

The second switch 220 may be coupled between the first output electrode OE1 of the reference voltage generator 210 and the detection node D_ND. The second switch 220 may be turned on in response to the switch control signal SCS. For example, when the switch control signal SCS is activated, the second switch 220 may be turned on to provide the first reference voltage VREF 1 received from the first output electrode OE1 of the reference voltage generator 210 to the detection node D_ND. When the switch control signal SCS is deactivated, the second switch 220 may be turned off to float the detection node D_ND.

The drive voltage generation circuit 100a, the reference voltage generation circuit 200a, the comparator 300, the latch circuit 400, the first capacitor 410, and the second capacitor 420 included in the nonvolatile memory device 20a of FIG. 13 may be the same as the drive voltage generation circuit 100a, the reference voltage generation circuit 200a, the comparator 300, the latch circuit 400, the first capacitor 410, and the second capacitor 420 included in the leakage current detection device 10a of FIG. 2. In addition, the controller 700 included in the nonvolatile memory device 20a of FIG. 13 may perform an operation of the control circuit 450 included in the leakage current detection device 10a of FIG. 2.

As described above with reference to FIGS. 1 to 13, the nonvolatile memory device 20a including the leakage current detection device 10 according to example embodiments may selectively couple the test line TEST_LN to one of the string selection line SSL, the plurality of word lines WL1 to WLn, and the ground selection line GSL, charge the test line TEST_LN based on the drive voltage VD while the voltage of the detection node D_ND is maintained at the first reference voltage VREF1, and then float the test line TEST_LN and the detection node D_ND. When a drive line coupled to the test line TEST_LN has a defect such that a leakage current flows from the test line TEST_LN, the voltage of the test line TEST_LN may decrease, and the voltage of the detection node D_ND may also decrease due to a coupling effect caused by the first capacitor 410 and the second capacitor 420. The comparator 300 may output the comparison signal CMP having the logic high level when the voltage of the detection node D_ND is lower than the second reference voltage VREF2. Since the latch circuit 400 latches the comparison signal CMP in response to the latch control signal LCS and outputs the latched comparison signal as the test result signal TEST_RE, the test result signal TEST_RE may indicate whether a leakage current flows from the drive line coupled to the test line TEST_LN.

Therefore, the nonvolatile memory device 20a including the leakage current detection device 10 according to example embodiments may effectively detect a leakage current flowing from the string selection line SSL, the plurality of word lines WL1 to WLn, and the ground selection line GSL.

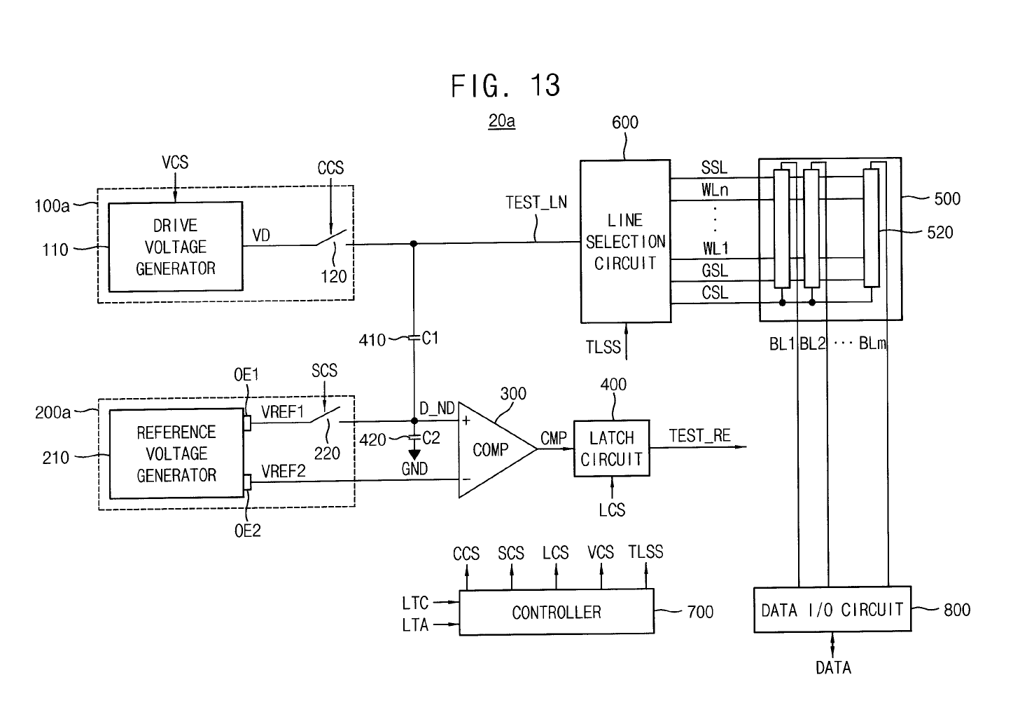

FIG. 14 is a block diagram illustrating an example of a nonvolatile memory device of FIG. 11.

Referring to FIG. 14, a nonvolatile memory device 20b may include a memory cell array 500, a line selection circuit 600, a controller 700, a data I/O circuit 800, a drive voltage generation circuit 100a, a reference voltage generation circuit 200a, a comparator 300, a latch circuit 400, a first capacitor 410, a second capacitor 420, a third switch 430, a fifth switch 460, and a current source 470.

The nonvolatile memory device 20b of FIG. 14 may be the same as the nonvolatile memory device 20a of FIG. 13 except that the nonvolatile memory device 20b of FIG. 14 may further include the third switch 430, the fifth switch 460, and the current source 470 from the nonvolatile memory device 20a of FIG. 13, and the controller 700 included in the nonvolatile memory device 20b of FIG. 14 may receive the comparison signal CMP from the comparator 300 and further generate a ground control signal GCS and a preset control signal PCS.

The third switch 430 may be coupled between the detection node D_ND and the ground voltage GND. The third switch 430 may be turned on in response to the ground control signal GCS provided by the controller 700. For example, when the ground control signal GCS is activated, the third switch 430 may be turned on to couple the detection node D_ND to the ground voltage GND such that the voltage V_D_ND of the detection node D_ND may be kept at the ground voltage GND. When the ground control signal GCS is deactivated, the third switch 430 may be turned off to disconnect the detection node D_ND from the ground voltage GND.

In some example embodiments, the third switch 430 may include an NMOS transistor having a gate on which the ground control signal GCS is applied.

The current source 470 may be coupled between the fifth switch 460 and the ground voltage GND. The current source 470 may generate a constant current Io having a predetermined magnitude.

In some example embodiments, a magnitude of the constant current Io may correspond to a minimum magnitude of a leakage current to be detected. For example, if a leakage current flowing from the string selection line SSL, the plurality of word lines WL1 to WLn, and the ground selection line GSL is required to be detected up to A amperes, the magnitude of the constant current To may be set to A amperes.

The fifth switch 460 may be coupled between the test line TEST_LN and the current source 470. The fifth switch 460 may be turned on in response to the preset control signal PCS provided by the controller 700. For example, when the preset control signal PCS is activated, the fifth switch 460 may be turned on to flow the constant current To from the test line TEST_LN to the ground voltage GND such that the voltage V_TEST_LN of the test line TEST_LN may decrease. When the preset control signal PCS is deactivated, the fifth switch 460 may be turned off to prevent the constant current To from flowing from the test line TEST_LN to the ground voltage GND.

In some example embodiments, the fifth switch 460 may include an NMOS transistor having a gate on which the preset control signal PCS is applied.

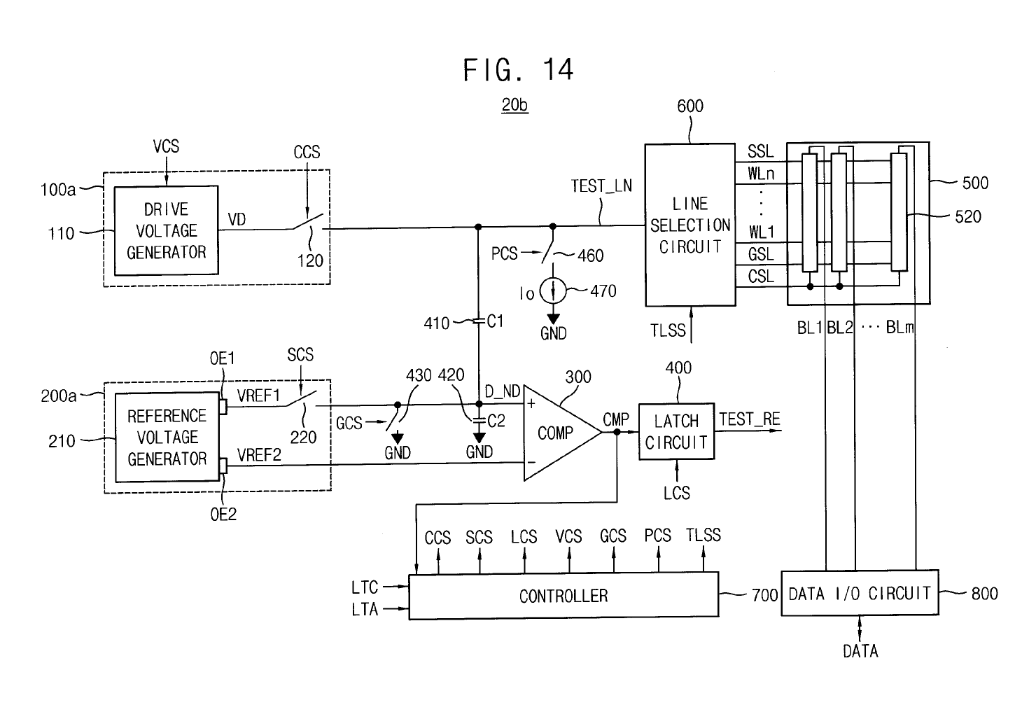

An operation of the controller 700 will be described below with reference to FIGS. 15, 16 and 17.

FIGS. 15, 16 and 17 are timing diagrams for describing an operation of the nonvolatile memory device of FIG. 14.

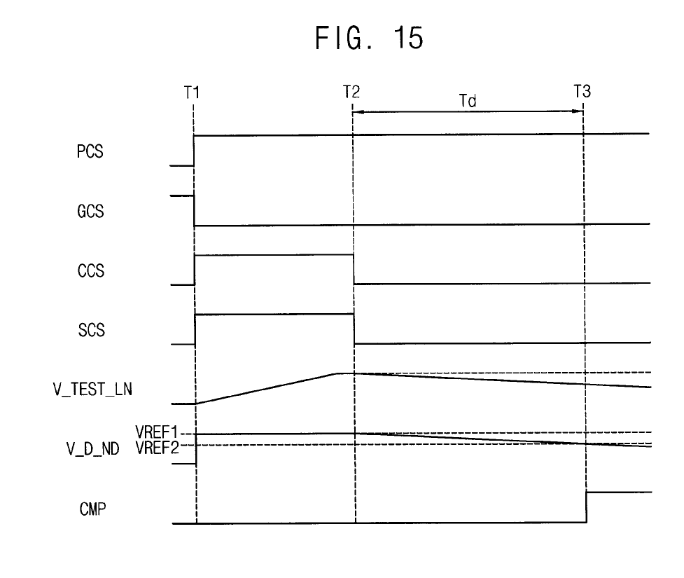

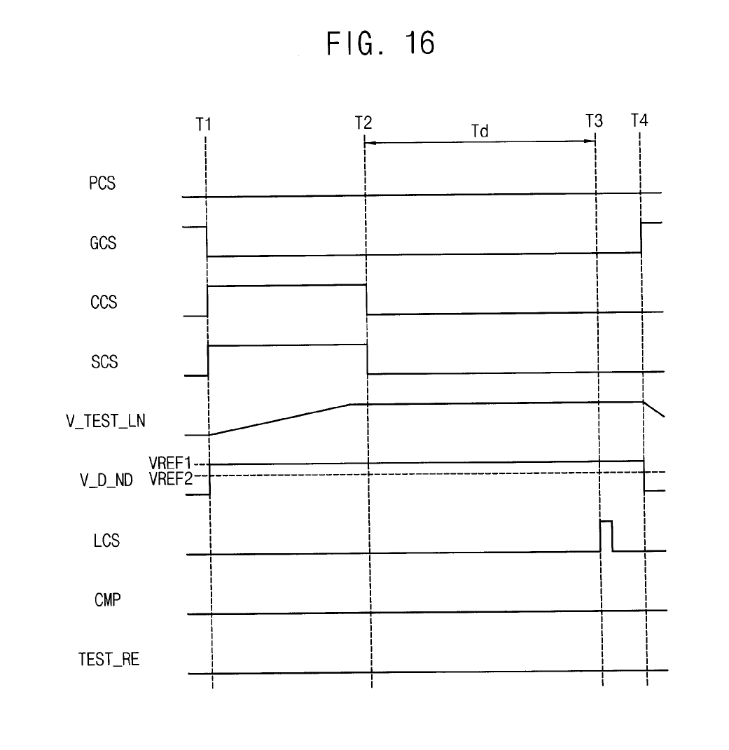

FIG. 15 illustrates an operation of the nonvolatile memory device 20b of FIG. 14 to determine a detection time Td that is used in performing a leakage test operation. FIG. 16 illustrates an operation of the nonvolatile memory device 20b of FIG. 14 when a leakage current does not flow from a drive line coupled to the test line TEST_LN. FIG. 17 illustrates an operation of the nonvolatile memory device 20b of FIG. 14 when a leakage current flows from a drive line coupled to the test line TEST_LN.

When the controller 700 receives the leakage test command LTC and the leakage test address LTA from outside, the controller 700 may generate the test line selection signal TLSS based on the leakage test address LTA. The line selection circuit 600 may connect the test line TEST_LN to one of the string selection line SSL, the plurality of word lines WL1 to WLn, and the ground selection line GSL that is indicated by the test line selection signal

TLSS.

After that, referring to FIG. 15, at a first time T1, the controller 700 may provide the ground control signal GCS deactivated at the logic low level to the third switch 430 to turn off the third switch 430, and provide the preset control signal PCS activated at the logic high level to the fifth switch 460 to turn on the fifth switch 460. In addition, the controller 700 may provide the charge control signal CCS activated at the logic high level to the first switch 120 to turn on the first switch 120, and provide the switch control signal SCS activated at the logic high level to the second switch 220 to turn on the second switch 220.

In FIG. 15, the charge control signal CCS and the switch control signal SCS are illustrated to be activated at the same time. However, example embodiments are not limited thereto. In some example embodiments, the charge control signal CCS and the switch control signal SCS may be activated with a time interval.

Since the third switch 430 is turned off and the second switch 220 is turned on, the voltage V_D_ND of the detection node D_ND may increase to the first reference voltage VREF1.

In addition, since the first switch 120 is turned on, the test line TEST_LN may be charged with charges provided by the drive voltage generator 110 such that the voltage V_TEST_LN of the test line TEST_LN may increase. Although the fifth switch 460 is turned on such that the constant current Io flows from the test line TEST_LN to the ground voltage GND, the voltage V_TEST_LN of the test line TEST_LN may increase up to a voltage determined based on the magnitude of the drive voltage VD generated by the drive voltage generator 110 since the magnitude of the constant current Io is relatively small compared to the charges provided by the drive voltage generator 110.

The voltage V_TEST_LN of the test line TEST_LN may be changed based on the magnitude of the drive voltage VD generated by the drive voltage generator 110.

In some example embodiments, the controller 700 may adjust the magnitude of the voltage control signal VCS, and the drive voltage generator 110 may adjust the magnitude of the drive voltage VD based on the magnitude of the voltage control signal VCS.

In some example embodiments, the controller 700 may adjust the magnitude of the voltage control signal VCS based on a type of a drive line to which the test line TEST_LN is coupled. For example, when one of the plurality of word lines WL1 to WLn, which deliver a signal having a relatively high voltage to the memory cell array 500, is coupled to the test line TEST_LN, the controller 700 may increase the magnitude of the voltage control signal VCS. When one of the string selection line SSL and the ground selection line GSL, which deliver a signal having a relatively low voltage to the memory cell array 500, is coupled to the test line TEST_LN, the controller 700 may decrease the magnitude of the voltage control signal VCS.

Therefore, the controller 700 may control a charge level of the test line TEST_LN by adjusting the magnitude of the voltage control signal VCS.

At a second time T2, the controller 700 may provide the charge control signal CCS deactivated at the logic low level to the first switch 120 to turn off the first switch 120, and provide the switch control signal SCS deactivated at the logic low level to the second switch 220 to turn off the second switch 220.

In FIG. 15, the charge control signal CCS and the switch control signal SCS are illustrated to be deactivated at the same time. However, example embodiments are not limited thereto. In some example embodiments, the charge control signal CCS and the switch control signal SCS may be deactivated with a time interval.

Since the test line TEST_LN is disconnected from the drive voltage VD and the detection node D_ND is disconnected from the first reference voltage VREF1, the test line TEST_LN and the detection node D_ND may be floated.

Since the fifth switch 460 is turned on such that the constant current To flows from the test line TEST_LN to the ground voltage GND, as illustrated in FIG. 15, the voltage V_TEST_LN of the test line TEST_LN may decrease based on the constant current Io.

Since the test line TEST_LN and the detection node D_ND are floated at the second time T2, as the voltage V_TEST_LN of the test line TEST_LN decreases, the voltage V_D_ND of the detection node D_ND may also decrease due to a coupling effect caused by the first capacitor 410 and the second capacitor 420.

As illustrated in FIG. 15, the comparator 300 may output the comparison signal CMP having the logic high level at a time when the voltage V_D_ND of the detection node D_ND is lower than the second reference voltage VREF2.

The controller 700 may determine the detection time Td as a time duration between the second time T2 and a time at which a logic level of the comparison signal CMP changes to the logic high level.

Therefore, the detection time Td may represent a time duration required for the voltage V_D_ND of the detection node D_ND to decrease from the first reference voltage VREF1 to the second reference voltage VREF2 when the constant current To flows from the test line TEST_LN to the ground voltage GND.

After the controller 700 determines the detection time Td, as illustrated in FIGS. 16 and 17, the controller 700 may maintain the preset control signal PCS in a deactivated state such that the fifth switch 460 may be maintained in a turned off state while the leakage test operation is performed.

Hereinafter, an operation of the nonvolatile memory device 20b of FIG. 14 in the case that a leakage current does not flow from a drive line coupled to the test line TEST_LN is described with reference to FIGS. 14 and 16.

After the controller 700 determines the detection time Td, at a first time T1, the controller 700 may provide the ground control signal GCS deactivated at the logic low level to the third switch 430 to turn off the third switch 430. In addition, the controller 700 may provide the charge control signal CCS activated at the logic high level to the first switch 120 to turn on the first switch 120, and provide the switch control signal SCS activated at the logic high level to the second switch 220 to turn on the second switch 220.

In FIG. 16, the charge control signal CCS and the switch control signal SCS are illustrated to be activated at the same time. However, example embodiments are not limited thereto. In some example embodiments, the charge control signal CCS and the switch control signal SCS may be activated with a time interval.

Since the third switch 430 is turned off and the second switch 220 is turned on, the voltage V_D_ND of the detection node D_ND may increase to the first reference voltage VREF1.

In addition, since the first switch 120 is turned on, the test line TEST_LN may be charged with charges provided by the drive voltage generator 110 such that the voltage V_TEST_LN of the test line TEST_LN may increase. The voltage V_TEST_LN of the test line TEST_LN may be changed based on the magnitude of the drive voltage VD generated by the drive voltage generator 110.

In some example embodiments, the controller 700 may adjust the magnitude of the voltage control signal VCS, and the drive voltage generator 110 may adjust the magnitude of the drive voltage VD based on the magnitude of the voltage control signal VCS.

At a second time T2, the controller 700 may provide the charge control signal CCS deactivated at the logic low level to the first switch 120 to turn off the first switch 120, and provide the switch control signal SCS deactivated at the logic low level to the second switch 220 to turn off the second switch 220.

In FIG. 16, the charge control signal CCS and the switch control signal SCS are illustrated to be deactivated at the same time. However, example embodiments are not limited thereto. In some example embodiments, the charge control signal CCS and the switch control signal SCS may be deactivated with a time interval.

Since the test line TEST_LN is disconnected from the drive voltage VD and the detection node D_ND is disconnected from the first reference voltage VREF1, the test line TEST_LN and the detection node D_ND may be floated.

When a leakage current does not flow from the drive line coupled to the test line TEST_LN, as illustrated in FIG. 16, the voltage V_TEST_LN of the test line TEST_LN may be maintained without a substantial change after the second time T2. Since the voltage V_TEST_LN of the test line TEST_LN is maintained without a substantial change after the second time T2, the voltage V_D_ND of the detection node D_ND may also be maintained at the first reference voltage VREF1 without a substantial change.

At a third time T3, the controller 700 may provide the latch control signal LCS activated at the logic high level to the latch circuit 400. Therefore, the latch circuit 400 may latch the comparison signal CMP output from the comparator 300 at the third time T3, and output the latched comparison signal as the test result signal TEST_RE. The time duration between the second time T2 and the third time T3 may correspond to the detection time Td, which is determined by an operation described above with reference to FIG. 15.

As illustrated in FIG. 16, when a leakage current does not flow from the drive line coupled to the test line TEST_LN, the voltage V_D_ND of the detection node D_ND at the third time T3 may correspond to the first reference voltage VREF1, which is higher than the second reference voltage VREF2. Therefore, the comparator 300 may output the comparison signal CMP having the logic low level, and the latch circuit 400 may output the test result signal TEST_RE having the logic low level.

At a fourth time T4, the controller 700 may provide the ground control signal GCS activated at the logic high level to the third switch 430 to turn on the third switch 430. Therefore, the voltage V_D_ND of the detection node D_ND may become the ground voltage GND and be maintained at the ground voltage GND. The leakage test operation may be finished at the fourth time T4.

Hereinafter, an operation of the nonvolatile memory device 20b of FIG. 14 in the case that a leakage current flows from a drive line coupled to the test line TEST_LN is described with reference to FIGS. 14 and 17.

After the controller 700 determines the detection time Td, at a first time T1, the controller 700 may provide the ground control signal GCS deactivated at the logic low level to the third switch 430 to turn off the third switch 430. In addition, the controller 700 may provide the charge control signal CCS activated at the logic high level to the first switch 120 to turn on the first switch 120, and provide the switch control signal SCS activated at the logic high level to the second switch 220 to turn on the second switch 220.

In FIG. 17, the charge control signal CCS and the switch control signal SCS are illustrated to be activated at the same time. However, example embodiments are not limited thereto. In some example embodiments, the charge control signal CCS and the switch control signal SCS may be activated with a time interval.

Since the third switch 430 is turned off and the second switch 220 is turned on, the voltage V_D_ND of the detection node D_ND may increase to the first reference voltage VREF1.

In addition, since the first switch 120 is turned on, the test line TEST_LN may be charged with charges provided by the drive voltage generator 110 such that the voltage V_TEST_LN of the test line TEST_LN may increase. The voltage V_TEST_LN of the test line TEST_LN may be changed based on the magnitude of the drive voltage VD generated by the drive voltage generator 110.

In some example embodiments, the controller 700 may adjust the magnitude of the voltage control signal VCS, and the drive voltage generator 110 may adjust the magnitude of the drive voltage VD based on the magnitude of the voltage control signal VCS.

At a second time T2, the controller 700 may provide the charge control signal CCS deactivated at the logic low level to the first switch 120 to turn off the first switch 120, and provide the switch control signal SCS deactivated at the logic low level to the second switch 220 to turn off the second switch 220.

In FIG. 17, the charge control signal CCS and the switch control signal SCS are illustrated to be deactivated at the same time. However, example embodiments are not limited thereto. In some example embodiments, the charge control signal CCS and the switch control signal SCS may be deactivated with a time interval.

Since the test line TEST_LN is disconnected from the drive voltage VD and the detection node D_ND is disconnected from the first reference voltage VREF1, the test line TEST_LN and the detection node D_ND may be floated.

When the drive line coupled to the test line TEST_LN has a defect such that a leakage current flows from the test line TEST_LN, as illustrated in FIG. 17, the voltage V_TEST_LN of the test line TEST_LN may decrease based on the leakage current after the second time T2.

Since the test line TEST_LN and the detection node D_ND are floated at the second time T2, as the voltage V_TEST_LN of the test line TEST_LN decreases, the voltage V_D_ND of the detection node D_ND may also decrease due to a coupling effect caused by the first capacitor 410 and the second capacitor 420.

As illustrated in FIG. 17, the comparator 300 may output the comparison signal CMP having the logic high level at a time when the voltage V_D_ND of the detection node D_ND is lower than the second reference voltage VREF2.

At a third time T3, the controller 700 may provide the latch control signal LCS activated at the logic high level to the latch circuit 400. Therefore, the latch circuit 400 may latch the comparison signal CMP output from the comparator 300 at the third time T3, and output the latched comparison signal as the test result signal TEST_RE. The time duration between the second time T2 and the third time T3 may correspond to the detection time Td, which is determined by an operation described above with reference to FIG. 15.

The greater a magnitude of the leakage current flowing from the test line TEST_LN is, the greater a decrease rate of the voltage V_TEST_LN of the test line TEST_LN during the detection time Td. Alternately, the smaller the magnitude of the leakage current flowing from the test line TEST_LN is, the smaller a decrease rate of the voltage V_TEST_LN of the test line TEST_LN during the detection time Td.

When the magnitude of the leakage current flowing from the test line TEST_LN is greater than the magnitude of the constant current Io, as illustrated in FIG. 17, the voltage V_D_ND of the detection node D_ND may be lower than the second reference voltage VREF2 before the third time T3. In this case, the comparator 300 may output the comparison signal CMP having the logic high level, and the latch circuit 400 may output the test result signal TEST_RE having the logic high level at the third time T3.

On the other hand, when the magnitude of the leakage current flowing from the test line TEST_LN is smaller than the magnitude of the constant current Io, the voltage V_D_ND of the detection node D_ND may be higher than the second reference voltage VREF2 at the third time T3. In this case, the comparator 300 may output the comparison signal CMP having the logic low level, and the latch circuit 400 may output the test result signal TEST_RE having the logic low level at the third time T3.

Therefore, the nonvolatile memory device 20b may detect a leakage current flowing from the string selection line SSL, the plurality of word lines WL1 to WLn, and the ground selection line GSL when a magnitude of the leakage current is equal to or greater than the magnitude of the constant current Io.

At a fourth time T4, the controller 700 may provide the ground control signal GCS activated at the logic high level to the third switch 430 to turn on the third switch 430. Therefore, the voltage V_D_ND of the detection node D_ND may become the ground voltage GND and be maintained at the ground voltage GND. The leakage test operation may be finished at the fourth time T4.

A signal having a relatively high voltage may be applied to the plurality of word lines WL1 to WLn during a program operation. Therefore, when the test line TEST_LN is coupled to one of the plurality of word lines WL1 to WLn, the voltage V_TEST_LN of the test line TEST_LN may become relatively high during the program operation.

Since the nonvolatile memory device 20b of FIG. 14 includes the third switch 430 that is turned on after finishing the leakage test operation, the voltage V_D_ND of the detection node D_ND may be maintained at the ground voltage GND without increasing to a high voltage although a signal having a relatively high voltage is applied to the test line TEST_LN during the program operation. Therefore, the comparator 300, which is coupled to the detection node D_ND, may be implemented using elements operating in a low voltage range.

In addition, since the nonvolatile memory device 20b of FIG. 14 determines a length of the detection time Td using the fifth switch 460 and the current source 470, the magnitude of the leakage current that the nonvolatile memory device 20b is able to detect may be determined based on the magnitude of the constant current Io.

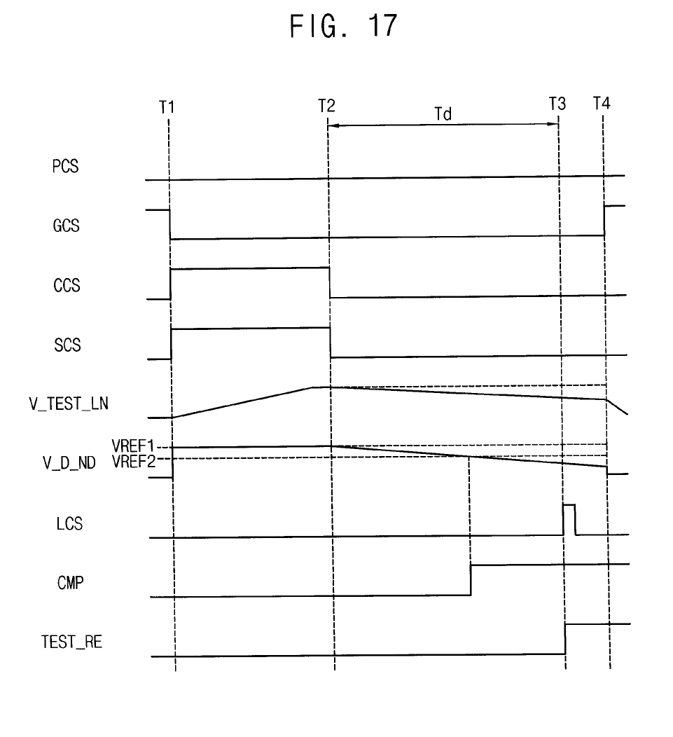

FIG. 18 is a block diagram illustrating a nonvolatile memory device according to example embodiments.

Referring to FIG. 18, a nonvolatile memory device 30 may include a memory cell array 500, an address decoder 601, a controller 701, a data I/o circuit 800, a drive voltage generation circuit 101, a reference voltage generation circuit 200a, a comparator 300, a latch circuit 400, a first capacitor 410, a second capacitor 420, a third switch 430, a fifth switch 460, and a current source 470.

The drive voltage generation circuit 101 may include a drive voltage generator 111 and a first switch 120.

The reference voltage generation circuit 200a may include a reference voltage generator 210 and a second switch 220.

The memory cell array 500 included in the nonvolatile memory device 30 of FIG. 18 may be the same as the memory cell array 500 included in the nonvolatile memory device 20 of FIG. 11.

The controller 701 may control overall operations of the nonvolatile memory device 30 based on a command signal CMD and an address signal ADDR received from an external device such as a memory controller. For example, the controller 701 may control a program operation, a read operation, the erase operation, and a leakage test operation of the nonvolatile memory device 30 based on the command signal CMD and the address signal ADDR.

When the controller 701 receives the command signal CMD that does not correspond to a leakage test command, the controller 701 may provide a test enable signal T_EN in a deactivated state to the address decoder 601. In this case, the controller 701 may generate a row address RADDR and a column address CADDR based on the address signal ADDR. The controller 701 may provide the row address RADDR to the address decoder 601, and provide the column address CADDR to the data I/o circuit 800.

The drive voltage generator 111 may generate various voltages required for operations of the nonvolatile memory device 30, and provide the various voltages to the address decoder 601. For example, the drive voltage generator 111 may generate a program voltage, a pass voltage and a verification voltage that are used in the program operation, generate a read voltage that is used in the read operation, and generate an erase voltage that is used in the erase operation.

The address decoder 601 may be connected to the memory cell array 500 through a plurality of word lines WL1 to WLn, a string selection line SSL, a ground selection line GSL, and a common source line CSL. When the address decoder 601 receives the test enable signal T_EN in the deactivated state, the address decoder 601 may select one of the plurality of word lines WL1 to WLn based on the row address RADDR received from the controller 701, and provide various voltages received from the drive voltage generator 111 to the selected word line and the unselected word lines.

The data I/O circuit 800 may be connected to the memory cell array 500 through a plurality of bit lines BL1 to BLm. The data I/O circuit 800 may select at least one of the plurality of bit lines BL1 to BLm based on the column address CADDR received from the controller 701, output data DATA read from a memory cell connected to the selected at least one bit line to an external device, and write data DATA received from the external device in a memory cell connected to the selected at least one bit line.

In some example embodiments, the data I/O circuit 800 may include a sense amplifier, a page buffer, a column selection circuit, a write driver, a data buffer, etc.

When the controller 701 receives the command signal CMD that corresponds to the leakage test command, the controller 701 may provide the test enable signal T_EN in an activated state to the address decoder 601. In this case, the controller 701 may generate a test line selection signal TLSS based on the address signal ADDR, and provide the test line selection signal TLSS to the address decoder 601.

For example, the controller 701 may generate the test line selection signal TLSS indicating one of the string selection line SSL, the plurality of word lines WL1 to WLn, and the ground selection line GSL that is represented by the address signal ADDR.

When the address decoder 601 receives the test enable signal T_EN in the activated state, the address decoder 601 may connect a test line TEST_LN to one of the string selection line SSL, the plurality of word lines WL1 to WLn, and the ground selection line GSL based on the test line selection signal TLSS.

The drive voltage generator 111 may generate a drive voltage VD.

The first switch 120 may be coupled between the drive voltage generator 111 and the test line TEST_LN. The first switch 120 may be turned on in response to a charge control signal CCS received from the controller 701. For example, when the charge control signal CCS is activated, the first switch 120 may be turned on to provide the drive voltage VD generated by the drive voltage generator 111 to the test line TEST_LN. When the charge control signal CCS is deactivated, the first switch 120 may be turned off to float the test line TEST_LN.

In some example embodiments, the drive voltage generator 111 may adjust a magnitude of the drive voltage VD based on a voltage control signal VCS received from the controller 701.

In some example embodiments, the controller 701 may adjust a magnitude of the voltage control signal VCS based on a type of a drive line to which the test line TEST_LN is coupled. For example, when one of the plurality of word lines WL1 to WLn, which deliver a signal having a relatively high voltage to the memory cell array 500, is coupled to the test line TEST_LN, the controller 701 may increase the magnitude of the voltage control signal VCS. When one of the string selection line SSL and the ground selection line GSL, which deliver a signal having a relatively low voltage to the memory cell array 500, is coupled to the test line TEST_LN, the controller 701 may decrease the magnitude of the voltage control signal VCS.

Therefore, the controller 701 may control a charge level of the test line TEST_LN by adjusting the magnitude of the voltage control signal VCS.

The reference voltage generator 210 may generate a first reference voltage VREF1 and output the first reference voltage VREF1 through a first output electrode OE1. The reference voltage generator 210 may generate a second reference voltage VREF2 by dropping a voltage level of the first reference voltage VREF1 and provide the second reference voltage VREF2 to the comparator 300 through a second output electrode OE2.

The second switch 220 may be coupled between the first output electrode OE1 of the reference voltage generator 210 and a detection node D_ND. The second switch 220 may be turned on in response to a switch control signal SCS received from the controller 701. For example, when the switch control signal SCS is activated, the second switch 220 may be turned on to provide the first reference voltage VREF1 received from the first output electrode OE1 of the reference voltage generator 210 to the detection node D_ND. When the switch control signal SCS is deactivated, the second switch 220 may be turned off to float the detection node D_ND.

The comparator 300, the latch circuit 400, the first capacitor 410, and the second capacitor 420, the third switch 430, the fifth switch 460, and the current source 470 included in the nonvolatile memory device 30 of FIG. 18 may be the same as the comparator 300, the latch circuit 400, the first capacitor 410, and the second capacitor 420, the third switch 430, the fifth switch 460, and the current source 470 included in the nonvolatile memory device 20b of FIG. 14.

As described above, when the nonvolatile memory device 30 receives the command signal CMD corresponding to the leakage test command from an external device such as a memory controller, the nonvolatile memory device 30 may perform a leakage test on one of the string selection line SSL, the plurality of word lines WL1 to WLn, and the ground selection line GSL that is represented by the address signal ADDR, and provide a test result signal TEST_RE to the memory controller.

Therefore, the memory controller may effectively determine whether a leakage current flows from a drive line corresponding to the address signal ADDR based on the test result signal TEST_RE.

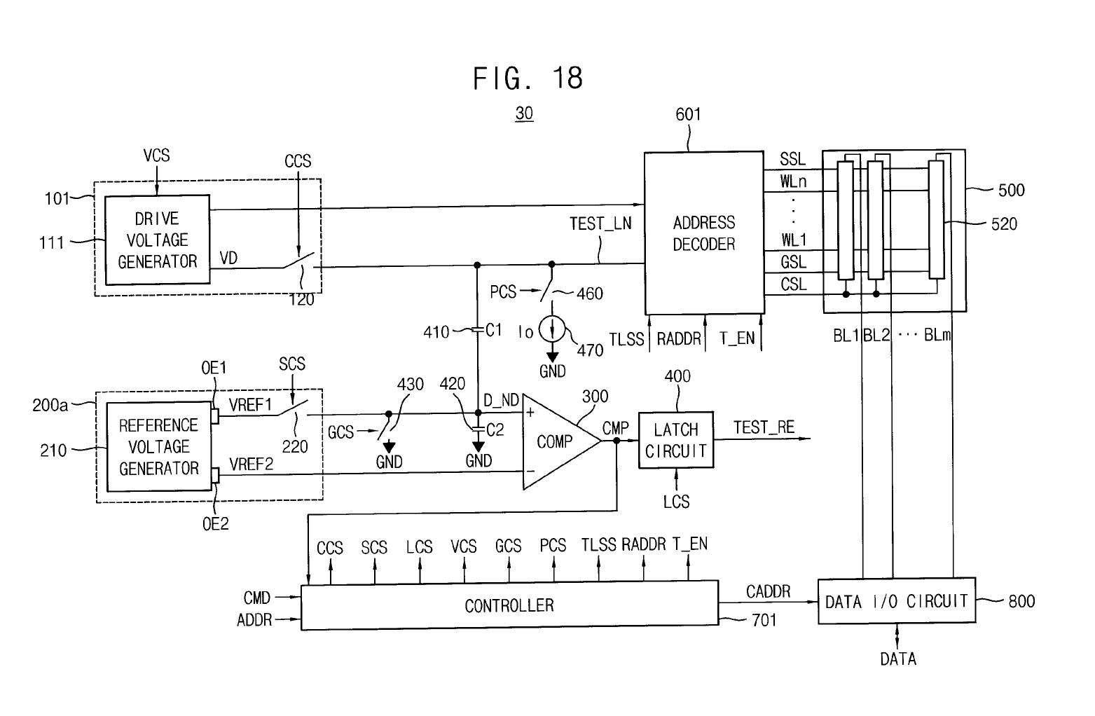

FIG. 19 is a flow chart illustrating a method of detecting a leakage current in a nonvolatile memory device according to example embodiments.

In FIG. 19, a method of detecting a leakage current flowing from a drive line coupled to a memory cell array of the nonvolatile memory device is represented.

Referring to FIG. 19, a first reference voltage and a second reference voltage lower than the first reference voltage are generated (step S100). In some example embodiments, the second reference voltage may be generated by dropping a voltage level of the first reference voltage.

A test line, which is coupled to one of a string selection line, a plurality of word lines, and a ground selection line that are coupled to the memory cell array, is charged by providing a drive voltage to the test line (step S200), and the first reference voltage is applied to a detection node, which is coupled to the test line through a first capacitor and is coupled to a ground voltage through a second capacitor (step S300).

After that, the test line and the detection node are floated (step S400). In some example embodiments, the test line may be floated by disconnecting the drive voltage from the test line, and the detection node may be floated by disconnecting the first reference voltage from the detection node. In some example embodiments, the test line and the detection node may be floated at the same time. In other example embodiments, the test line and the detection node may be floated with a time interval.

When the test line has a defect such that a leakage current flows from the test line, a voltage of the test line may decrease based on the leakage current. Since the test line and the detection node are floated, as the voltage of the test line decreases, a voltage of the detection node may also decrease due to a coupling effect caused by the first capacitor and the second capacitor.

On the other hand, when a leakage current does not flow from the test line, the voltage of the test line may be maintained without a substantial change, and the voltage of the detection node may also be maintained at the first reference voltage without a substantial change.

A test result signal, which indicates whether a leakage current flows from the test line, is generated by comparing the voltage of the detection node with the second reference voltage after a detection time from a time at which the test line and the detection node are floated (step S500).

In some example embodiments, when the voltage of the detection node is equal to or higher than the second reference voltage after a detection time from a time at which the test line and the detection node are floated, the test result signal having a logic low level may be generated. Alternately, when the voltage of the detection node is lower than the second reference voltage after the detection time from the time at which the test line and the detection node are floated, the test result signal having a logic high level may be generated.

Therefore, the method of detecting a leakage current in a nonvolatile memory device according to example embodiments may effectively detect a leakage current flowing from a drive line coupled to a memory cell array of the nonvolatile memory device.

In some example embodiments, after the test result signal is generated, the detection node may be coupled to the ground voltage (step S600).

Generally, a signal having a relatively high voltage may be applied to a word line of a nonvolatile memory device when a program operation is performed. Therefore, when the test line is coupled to a word line of the nonvolatile memory device, the voltage of the test line may become relatively high during a program operation.

In the method of detecting a leakage current in a nonvolatile memory device according to example embodiments, after finishing the leakage test operation by generating the test result signal, the voltage of the detection node may be maintained at the ground voltage without increasing to a high voltage although a signal having a relatively high voltage is applied to the test line during the program operation. Therefore, a comparator, which compares the voltage of the detection node with the second reference voltage, may be implemented using elements operating in a low voltage range.

The method of detecting a leakage current in a nonvolatile memory device illustrated in FIG. 19 may be performed by the nonvolatile memory device 20 of FIG. 11 or the nonvolatile memory device 30 of FIG. 18.

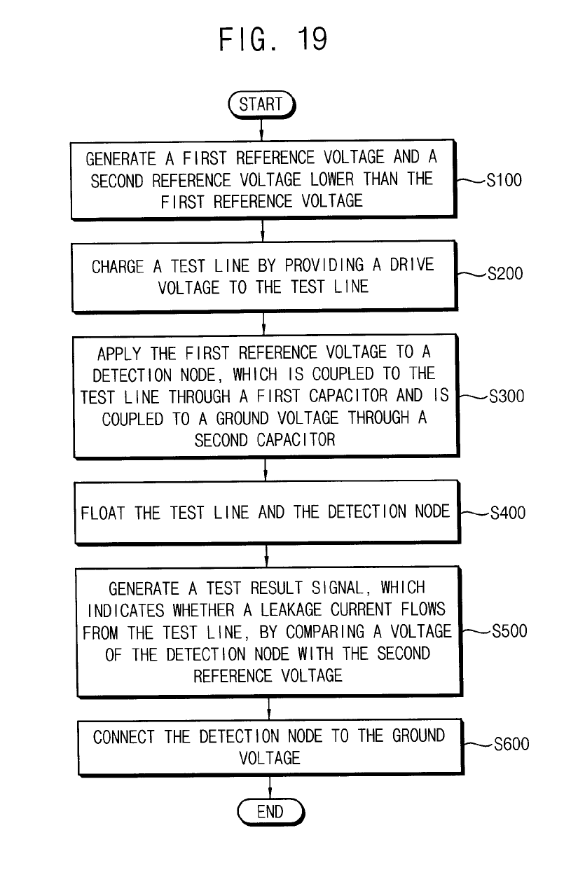

FIG. 20 is a block diagram illustrating a memory system according to example embodiments.

Referring to FIG. 20, a memory system 900 includes a memory controller 910 and a nonvolatile memory device 920.

The nonvolatile memory device 920 includes a memory cell array 921, a leakage current detection device 922 and a data I/O circuit 923.

The memory cell array 921 may include a plurality of memory cell strings. The plurality of memory cell strings may be coupled to the leakage current detection device 922 through a string selection line SSL, a plurality of word lines WL, and a ground selection line GSL.

The leakage current detection device 922 may select one of the string selection line SSL, the plurality of word lines WL, and the ground selection line GSL as a test line. The leakage current detection device 922 may generate a first reference voltage and a second reference voltage, and selectively provide the first reference voltage to a detection node, which is coupled to the test line through a first capacitor and is coupled to a ground voltage through a second capacitor. The leakage current detection device 922 may charge the test line using a drive voltage. After that, the leakage current detection device 922 may float the test line and the detection node. When the test line has a defect such that a leakage current flows from the test line, a voltage of the test line may decrease based on the leakage current. Since the test line and the detection node are floated, as the voltage of the test line decreases, a voltage of the detection node may also decrease due to a coupling effect caused by the first capacitor and the second capacitor. The leakage current detection device 922 may generate a test result signal, which indicates whether a leakage current flows from the test line, by comparing the voltage of the detection node with the second reference voltage after a detection time from a time at which the test line and the detection node are floated, and provide the test result signal TEST_RE to the memory controller 910.

The data I/O circuit 923 may be connected to the memory cell array 921 through a plurality of bit lines. The data I/O circuit 923 may select at least one of the plurality of bit lines, output data read from a memory cell connected to the selected at least one bit line to the memory controller 910, and write data received from the memory controller 910 in a memory cell connected to the selected at least one bit line.

The nonvolatile memory device 920 may be implemented with the nonvolatile memory device 20 of FIG. 11 or the nonvolatile memory device 30 of FIG. 18.

The memory controller 910 may control the nonvolatile memory device 920. The memory controller 910 may control data transfer between an external host and the nonvolatile memory device 920.

The memory controller 910 may include a central processing unit CPU 911, a buffer memory RAM 912, a host interface 913 and a memory interface 914.

The central processing unit 911 may perform operations for the data transfer. The buffer memory 912 may be implemented by a dynamic random access memory (DRAM), a static random access memory (SRAM), a phase change random access memory (PRAM), a ferroelectric random access memory (FRAM), a resistance random access memory (RRAM), a magnetic random access memory (MRAM), etc.

The buffer memory 912 may be an operational memory of the central processing unit 911. In some example embodiments, the buffer memory 912 may be included in the memory controller 910. In other example embodiments, the buffer memory 912 may be outside of the memory controller 910.

The host interface 913 may be coupled to the host, and the memory interface 914 may be coupled to the nonvolatile memory device 920. The central processing unit 911 may communicate with the host via the host interface 913. For example, the host interface 913 may be configured to communicate with the host using at least one of various interface protocols, such as a universal serial bus (USB), a multimedia card (MMC), a peripheral component interconnect-express (PCI-E), a small computer system interface (SCSI), a serial-attached SCSI (SAS), a serial advanced technology attachment (SATA), a parallel advanced technology attachment (PATA), an enhanced small disk interface (ESDI), integrated drive electronics (IDE), and so on.

Further, the central processing unit 911 may communicate with the nonvolatile memory device 920 via the memory interface 914.

In some example embodiments, the memory controller 910 may further include an error correction block 915 for error correction.

In some example embodiments, the memory controller 910 may be built in the nonvolatile memory device 920, or the memory controller 910 and the nonvolatile memory device 920 may be implemented as separate integrated circuit chips.

The memory system 900 may be implemented as a memory card, a solid state drive, and so on.

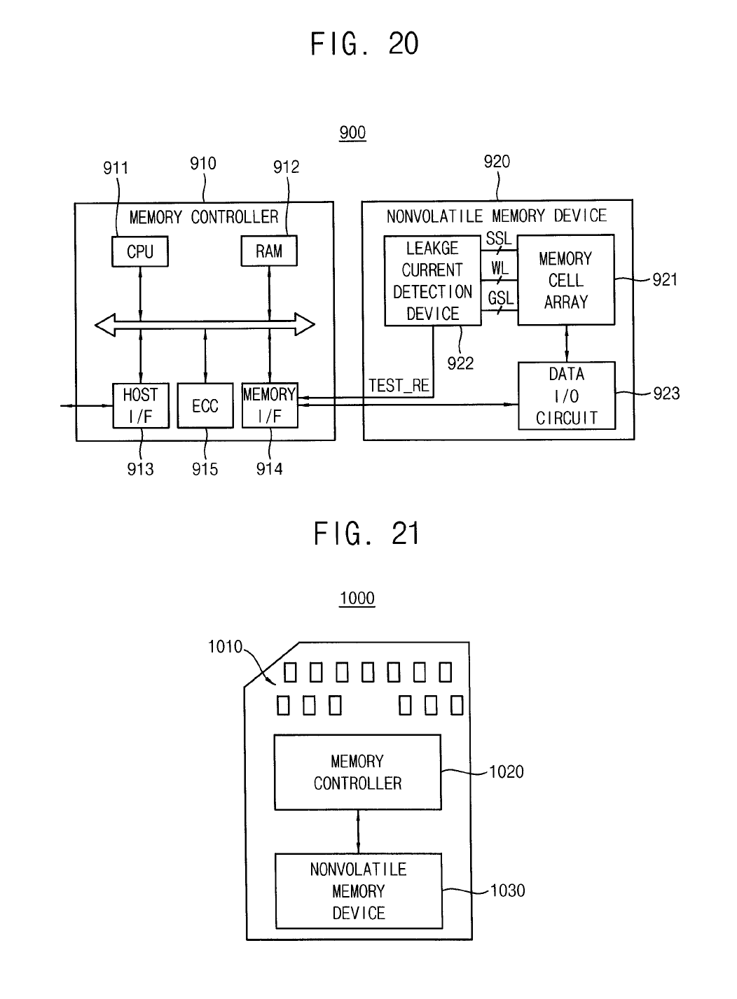

FIG. 21 is a block diagram illustrating a memory card according to example embodiments.

Referring to FIG. 21, a memory card 1000 includes a plurality of connecting pins 1010, a memory controller 1020 and a nonvolatile memory device 1030.

The connecting pins 1010 may be coupled to an external host to transfer signals between the host and the memory card 1000. The connecting pins 1010 may include a clock pin, a command pin, a data pin and/or a reset pin.

The memory controller 1020 may receive data from the host, and may store the received data in the nonvolatile memory device 1030.

A memory cell array included in the nonvolatile memory device 1030 may include a plurality of memory cell strings coupled to a string selection line, a plurality of word lines, and a ground selection line. The nonvolatile memory device 1030 may select one of the string selection line, the plurality of word lines, and the ground selection line as a test line. The nonvolatile memory device 1030 may generate a first reference voltage and a second reference voltage, and selectively provide the first reference voltage to a detection node, which is coupled to the test line through a first capacitor and is coupled to a ground voltage through a second capacitor. The nonvolatile memory device 1030 may charge the test line using a drive voltage. After that, the nonvolatile memory device 1030 may float the test line and the detection node. When the test line has a defect such that a leakage current flows from the test line, a voltage of the test line may decrease based on the leakage current. Since the test line and the detection node are floated, as the voltage of the test line decreases, a voltage of the detection node may also decrease due to a coupling effect caused by the first capacitor and the second capacitor. The nonvolatile memory device 1030 may generate a test result signal, which indicates whether a leakage current flows from the test line, by comparing the voltage of the detection node with the second reference voltage after a detection time from a time at which the test line and the detection node are floated.

The nonvolatile memory device 1030 may be implemented with the nonvolatile memory device 20 of FIG. 11 or the nonvolatile memory device 30 of FIG. 18.

The memory card 1000 may include an MMC, an embedded MMC (eMMC), a hybrid embedded MMC (hybrid eMMC), a secure digital (SD) card, a micro-SD card, a memory stick, an ID card, a personal computer memory card international association (PCMCIA) card, a chip card, a USB card, a smart card, a compact flash (CF) card, and so on.

In some example embodiments, the memory card 1000 may be coupled to the host, such as a desktop computer, a laptop computer, a tablet computer, a mobile phone, a smart phone, a music player, a personal digital assistant (PDA), a portable multimedia player (PMP), a digital television, a digital camera, a portable game console, and so on.

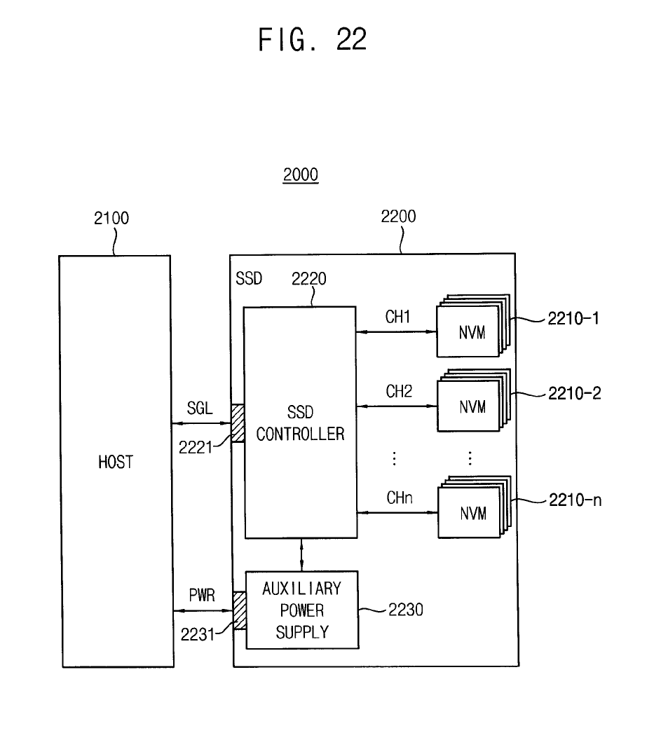

FIG. 22 is a block diagram illustrating a solid state drive (SSD) system according to example embodiments.

Referring to FIG. 22, a SSD system 2000 includes a host 2100 and a SSD 2200.

The SSD 2200 may include first through n-th nonvolatile memory devices 2210-1, 2210-2, . . . , 2210-n and a SSD controller 2220.

The first through n-th nonvolatile memory devices 2210-1, 2210-2, . . . , 2210-n may be used as a storage medium of the SSD 2200.

A memory cell array included in each of the first through n-th nonvolatile memory devices 2210-1, 2210-2, . . . , 2210-n may include a plurality of memory cell strings coupled to a string selection line, a plurality of word lines, and a ground selection line. Each of the first through n-th nonvolatile memory devices 2210-1, 2210-2, . . . , 2210-n may select one of the string selection line, the plurality of word lines, and the ground selection line as a test line. Each of the first through n-th nonvolatile memory devices 2210-1, 2210-2, . . . , 2210-n may generate a first reference voltage and a second reference voltage, and selectively provide the first reference voltage to a detection node, which is coupled to the test line through a first capacitor and is coupled to a ground voltage through a second capacitor. Each of the first through n-th nonvolatile memory devices 2210-1, 2210-2, . . . , 2210-n may charge the test line using a drive voltage. After that, each of the first through n-th nonvolatile memory devices 2210-1, 2210-2, . . . , 2210-n may float the test line and the detection node. When the test line has a defect such that a leakage current flows from the test line, a voltage of the test line may decrease based on the leakage current. Since the test line and the detection node are floated, as the voltage of the test line decreases, a voltage of the detection node may also decrease due to a coupling effect caused by the first capacitor and the second capacitor.

Each of the first through n-th nonvolatile memory devices 2210-1, 2210-2, . . . , 2210-n may generate a test result signal, which indicates whether a leakage current flows from the test line, by comparing the voltage of the detection node with the second reference voltage after a detection time from a time at which the test line and the detection node are floated.

Each of the first through n-th nonvolatile memory devices 2210-1, 2210-2, . . . , 2210-n may be implemented with the nonvolatile memory device 20 of FIG. 11 or the nonvolatile memory device 30 of FIG. 18.

The SSD controller 2220 may be coupled to the first through n-th nonvolatile memory devices 2210-1, 2210-2, . . . , 2210-n by first through n-th channels CH1, CH2, . . . , CHn, respectively.

The SSD controller 2220 may exchange a signal SGL with the host 2100 through a signal connector 2221. The signal SGL may include a command, an address and data. The SSD controller 2220 may perform a program operation and a read operation on the first through n-th nonvolatile memory devices 2210-1, 2210-2, . . . , 2210-n according to the command received from the host 2100.

The SSD 2200 may further include an auxiliary power supply 2230. The auxiliary power supply 2230 may receive power PWR from the host 2100 through a power connector 2231 and provide power to the SSD controller 2220. The auxiliary power supply 2230 may be placed inside or outside the SSD 2200. For example, the auxiliary power supply 2230 may be placed in a main board and provide auxiliary power to the SSD 2200.

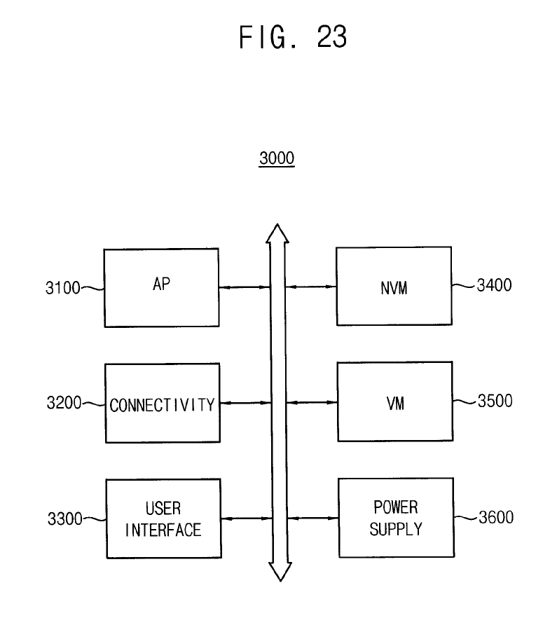

FIG. 23 is a block diagram illustrating a mobile system according to example embodiments.

Referring to FIG. 23, a mobile system 3000 includes an application processor AP 3100, a connectivity unit 3200, a user interface 3300, a nonvolatile memory device NVM 3400, a volatile memory device VM 3500 and a power supply 3600.

In some embodiments, the mobile system 3000 may be a mobile phone, a smart phone, a personal digital assistant (PDA), a portable multimedia player (PMP), a digital camera, a music player, a portable game console, a navigation system, etc.

The application processor 3100 may execute applications, such as a web browser, a game application, a video player, etc. In some example embodiments, the application processor 3100 may include a single core or multiple cores. For example, the application processor 3100 may be a multi-core processor, such as a dual-core processor, a quad-core processor, a hexa-core processor, etc. The application processor 3100 may include an internal or external cache memory.

The connectivity unit 3200 may perform wired or wireless communication with an external device. For example, the connectivity unit 3200 may perform Ethernet communication, near field communication (NFC), radio frequency identification (RFID) communication, mobile telecommunication, memory card communication, universal serial bus (USB) communication, etc. In some embodiments, the connectivity unit 3200 may include a baseband chipset that supports communications, such as global system for mobile communications (GSM), general packet radio service (GPRS), wideband code division multiple access (WCDMA), high speed downlink/uplink packet access (HSxPA), etc.

The nonvolatile memory device 3400 may store a boot image for booting the mobile system 3000.

A memory cell array included in the nonvolatile memory device 3400 may include a plurality of memory cell strings coupled to a string selection line, a plurality of word lines, and a ground selection line. The nonvolatile memory device 3400 may select one of the string selection line, the plurality of word lines, and the ground selection line as a test line. The nonvolatile memory device 3400 may generate a first reference voltage and a second reference voltage, and selectively provide the first reference voltage to a detection node, which is coupled to the test line through a first capacitor and is coupled to a ground voltage through a second capacitor. The nonvolatile memory device 3400 may charge the test line using a drive voltage. After that, the nonvolatile memory device 3400 may float the test line and the detection node. When the test line has a defect such that a leakage current flows from the test line, a voltage of the test line may decrease based on the leakage current.

Since the test line and the detection node are floated, as the voltage of the test line decreases, a voltage of the detection node may also decrease due to a coupling effect caused by the first capacitor and the second capacitor. The nonvolatile memory device 3400 may generate a test result signal, which indicates whether a leakage current flows from the test line, by comparing the voltage of the detection node with the second reference voltage after a detection time from a time at which the test line and the detection node are floated.

The nonvolatile memory device 3400 may be implemented with the nonvolatile memory device 20 of FIG. 11 or the nonvolatile memory device 30 of FIG. 18.

The volatile memory device 3500 may store data processed by the application processor 3100, or may operate as a working memory.

The user interface 3300 may include at least one input device, such as a keypad, a touch screen, etc., and at least one output device, such as a speaker, a display device, etc.

The power supply 3600 may supply a power supply voltage to the mobile system 3000.

In some embodiments, the mobile system 3000 may further include an image processor, and/or a storage device, such as a memory card, a solid state drive (SSD), a hard disk drive (HDD), a CD-ROM, etc.

In some embodiments, the mobile system 3000 and/or components of the mobile system 3000 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP).

The foregoing is illustrative of the present application and is not to be construed as limiting thereof. Although a few example embodiments have been described, those skilled in the art will readily appreciate that many modifications are possible in the example embodiments without materially departing from the novel teachings and advantages of the present application. Accordingly, all such modifications are intended to be included within the scope of the present application as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A leakage current detection device comprising:
a drive voltage generation circuit configured to provide a drive voltage to a test line, in response to a charge control signal, to charge the test line;
a reference voltage generation circuit configured to generate a first reference voltage and a second reference voltage and to provide the first reference voltage to a detection node in response to a switch control signal;
a first capacitor coupled between the test line and the detection node;
a second capacitor coupled between the detection node and a ground voltage;
a comparator configured to output a comparison signal by comparing a voltage of the detection node with the second reference voltage; and
a latch circuit configured to latch the comparison signal in response to a latch control signal and to output the latched comparison signal as a test result signal indicating whether a leakage current flows from the test line.

2. The leakage current detection device of claim 1, wherein the drive voltage generation circuit includes:
a drive voltage generator configured to generate the drive voltage; and
a switch coupled between the drive voltage generator and the test line, the switch being turned on in response to the charge control signal.

3. The leakage current detection device of claim 2, wherein the drive voltage generator adjusts a magnitude of the drive voltage based on a voltage control signal.

4. The leakage current detection device of claim 1, wherein the reference voltage generation circuit includes:
a reference voltage generator configured to generate the first reference voltage and to output the first reference voltage through a first output electrode, the reference voltage generator being configured to generate the second reference voltage by dropping a voltage level of the first reference voltage and to provide the second reference voltage to the comparator through a second output electrode; and
a first switch coupled between the first output electrode of the reference voltage generator and the detection node, the first switch being turned on in response to the switch control signal.

5. The leakage current detection device of claim 4, further comprising:
a control circuit configured to generate the charge control signal, the switch control signal, and the latch control signal, wherein:
the control circuit activates the charge control signal and the switch control signal at a first time, deactivates the charge control signal and the switch control signal at a second time, and provides the latch control signal to the latch circuit at a third time, and the time duration between the second time and the third time corresponds to a detection time.

6. The leakage current detection device of claim 5, wherein the control circuit adjusts a length of the detection time based on a magnitude of the leakage current of the test line to be detected.

7. The leakage current detection device of claim 4, further comprising a second switch coupled between the detection node and the ground voltage, the second switch being turned on in response to a ground control signal after the latch circuit outputs the test result signal in response to the latch control signal.

8. The leakage current detection device of claim 1, wherein the reference voltage generation circuit includes:
a switch coupled between the detection node and the ground voltage, the switch being turned on to provide the ground voltage to the detection node as the first reference voltage when the switch control signal is activated, the switch being turned off to float the detection node when the switch control signal is deactivated; and
a reference voltage generator configured to generate the second reference voltage and to provide the second reference voltage to the comparator.

9. The leakage current detection device of claim 8, further comprising:
a control circuit configured to generate the charge control signal, the switch control signal, and the latch control signal, wherein:
the control circuit activates the charge control signal and deactivates the switch control signal at a first time, deactivates the charge control signal at a second time, and provides the latch control signal to the latch circuit at a third time, and
the time duration between the second time and the third time corresponds to a detection time.

10. The leakage current detection device of claim 1, wherein the test line corresponds to a word line coupled to a memory cell array of a nonvolatile memory device.

11. The leakage current detection device of claim 1, wherein the test line corresponds to a string selection line coupled to a memory cell array of a nonvolatile memory device.

12. The leakage current detection device of claim 1, wherein the test line corresponds to a ground selection line coupled to a memory cell array of a nonvolatile memory device.

13. A method of detecting a leakage current in a nonvolatile memory device, the method comprising:
generating a first reference voltage and a second reference voltage lower than the first reference voltage;
charging a test line, which is coupled to a string selection line, one of a plurality of word lines, or a ground selection line that is coupled to a memory cell array, by providing a drive voltage to the test line;
applying the first reference voltage to a detection node, which is coupled to the test line through a first capacitor and is coupled to a ground voltage through a second capacitor;
floating the test line and the detection node; and
generating a test result signal, which indicates whether a leakage current flows from the test line, by comparing a voltage of the detection node with the second reference voltage after a detection time from a time at which the test line and the detection node are floated.

14. The method of claim 13, further comprising connecting the detection node to the ground voltage after generating the test result signal.

15. A method of testing a nonvolatile memory device, the method comprising:
applying a charge voltage to a signal line of a memory cell array of the memory device; and
detecting an indication of the amount of leakage current flowing through the signal line of the memory cell array.

16. The method of claim 15, further comprising:
discontinuing the application of the charge voltage to the signal line, wherein the indication of the amount of leakage current flowing through the signal line is detected by comparing an indicator of the voltage existing on the signal line to a reference value, after a predetermined period of time has expired from discontinuing the application of the charge voltage to the signal line.

17. The method of claim 16, further comprising:
applying the charge voltage to a reference signal line of a standard nonvolatile memory cell array;
discontinuing the application of the charge voltage to the reference signal line;
determining, based upon an indicator of the voltage existing on the reference signal line, the amount of time expiring before the voltage existing on the reference test line decays to a standard value after discontinuing the application of the charge voltage to the reference signal line; and
setting the value of the predetermined period of time based upon the determined amount of time expiring before the voltage existing on the reference signal line decays to the standard value.
